(19) United States
(12) Patent Application Publication
(10) Pub. No.: US 2026/0024559 A1
(43) Pub. Date: Jan. 22, 2026

(54) SEMICONDUCTOR MEMORY DEVICE

(71) Applicant: Kioxia Corporation, Tokyo (JP)

(72) Inventors: Shinya ARAI, Yokkaichi (JP); Hideo WADA, Yokkaichi (JP)

(73) Assignee: Kioxia Corporation, Tokyo (JP)

(21) Appl. No.: 19/074,528

(22) Filed: Mar. 10, 2025

(30) Foreign Application Priority Data
Jul. 16, 2024 (JP) 2024-113163

(51) Int. Cl. G11C 5/06; G11C 16/04; H01L 23/00; H01L 25/065; H10B 43/10; H10B 43/27; H10B 43/35; H10B 80/00

(52) U.S. Cl. CPC G11C 5/063; G11C 16/0483; H01L 24/08; H01L 25/0657; H10B 43/10; H10B 43/27; H10B 43/35; H10B 80/00; H01L 2224/08221; H01L 2225/06541; H01L 2924/1438

(57) ABSTRACT

According to one embodiment, a semiconductor memory device includes: a first chip including a substrate defining a first region and a second region; and a second chip contacting the first chip in a first direction, the second chip being electrically connected to the first chip via a plurality of connection pads at a boundary region. The second chip includes a memory cell array, the memory cell array including a source line, word lines below the source line, and a memory pillar. The second chip further includes contacts extending in the first direction and each electrically connected to one of the connection pads, a conductor pattern contacting upper ends of the contacts, and a first interconnect extending above the conductor pattern and electrically connected to the conductor pattern.

### CROSS-REFERENCE TO RELATED APPLICATION(S)

This application is based upon and claims the benefit of priority from Japanese Patent Application No. 2024-113163, filed Jul. 16, 2024, the entire contents of which are incorporated herein by reference.

### FIELD

Embodiments described herein relate generally to a semiconductor memory device.

### BACKGROUND

As a semiconductor memory device capable of storing data in a nonvolatile manner, a NAND flash memory is known. A NAND flash memory adopts a three-dimensional memory structure for enhanced integration and increased capacity.

### BRIEF DESCRIPTION OF THE DRAWINGS

FIG. 1 is a block diagram showing an exemplary configuration of a memory system including a semiconductor memory device according to a first embodiment.

FIG. 2 is a circuit diagram showing an exemplary circuit configuration of a memory cell array in the semiconductor memory device according to the first embodiment.

FIG. 3 is a plan view showing an exemplary planar layout of the semiconductor memory device according to the first embodiment.

FIG. 4 is a plan view showing an exemplary planar layout of the memory cell array in the semiconductor memory device according to the first embodiment.

FIG. 5 is a plan view showing an exemplary planar layout of the memory cell array in the semiconductor memory device according to the first embodiment.

FIG. 6 is a sectional view taken along the line VI-VI indicated in FIG. 5 and shows an exemplary sectional structure of the memory cell array in the semiconductor memory device according to the first embodiment.

FIG. 7 is a sectional view taken along the line VII-VII indicated in FIG. 6 and shows an exemplary sectional structure of a memory pillar in the semiconductor memory device according to the first embodiment.

FIG. 8 is a sectional view showing an exemplary sectional structure of a circuit region in the semiconductor memory device according to the first embodiment.

FIG. 9 is a sectional view taken along the line IX-IX indicated in FIG. 8 and shows exemplary coupling portions between an interconnect layer and respective contacts in the semiconductor memory device according to the first embodiment.

FIG. 10 is a sectional view showing an exemplary sectional structure of connection pads in the semiconductor memory device according to the first embodiment.

FIG. 11 is a sectional view for explaining an exemplary method for manufacturing the semiconductor memory device according to the first embodiment.

FIG. 12 is a sectional view for explaining the exemplary method for manufacturing the semiconductor memory device according to the first embodiment.

FIG. 13 is a sectional view for explaining the exemplary method for manufacturing the semiconductor memory device according to the first embodiment.

FIG. 14 is a sectional view for explaining the exemplary method for manufacturing the semiconductor memory device according to the first embodiment.

FIG. 15 is a sectional view for explaining the exemplary method for manufacturing the semiconductor memory device according to the first embodiment.

FIG. 16 is a sectional view for explaining the exemplary method for manufacturing the semiconductor memory device according to the first embodiment.

FIG. 17 is a sectional view for explaining the exemplary method for manufacturing the semiconductor memory device according to the first embodiment.

FIG. 18 is a sectional view for explaining the exemplary method for manufacturing the semiconductor memory device according to the first embodiment.

FIG. 19 is a sectional view for explaining the exemplary method for manufacturing the semiconductor memory device according to the first embodiment.

FIG. 20 is a sectional view for explaining the exemplary method for manufacturing the semiconductor memory device according to the first embodiment.

FIG. 21 is a sectional view showing an exemplary sectional structure of a circuit region in a semiconductor memory device according to a first modification of the first embodiment.

FIG. 22 is a sectional view showing an exemplary sectional structure of a circuit region in a semiconductor memory device according to a second modification of the first embodiment.

FIG. 23 is a sectional view showing an exemplary sectional structure of a circuit region in a semiconductor memory device according to a third modification of the first embodiment.

FIG. 24 is a sectional view showing an exemplary sectional structure of a circuit region in a semiconductor memory device according to a fourth modification of the first embodiment.

FIG. 25 is a sectional view showing an exemplary sectional structure of a circuit region in a semiconductor memory device according to a fifth modification of the first embodiment.

FIG. 26 is a sectional view showing an exemplary sectional structure of the circuit region in the semiconductor memory device according to the fifth modification of the first embodiment.

FIG. 27 is a plan view showing an exemplary planar layout of a semiconductor memory device according to a second embodiment.

FIG. 28 is a sectional view showing an exemplary sectional structure of a circuit region in the semiconductor memory device according to the second embodiment.

FIG. 29 is a sectional view showing an exemplary sectional structure of the circuit region in the semiconductor memory device according to the second embodiment.

FIG. 30 is a sectional view for explaining an exemplary method for manufacturing the semiconductor memory device according to the second embodiment.

FIG. 31 is a sectional view for explaining the exemplary method for manufacturing the semiconductor memory device according to the second embodiment.

FIG. 32 is a sectional view for explaining the exemplary method for manufacturing the semiconductor memory device according to the second embodiment.

FIG. 33 is a sectional view for explaining the exemplary method for manufacturing the semiconductor memory device according to the second embodiment.

FIG. 34 is a sectional view for explaining the exemplary method for manufacturing the semiconductor memory device according to the second embodiment.

FIG. 35 is a sectional view for explaining the exemplary method for manufacturing the semiconductor memory device according to the second embodiment.

FIG. 36 is a sectional view for explaining the exemplary method for manufacturing the semiconductor memory device according to the second embodiment.

FIG. 37 is a sectional view for explaining the exemplary method for manufacturing the semiconductor memory device according to the second embodiment.

FIG. 38 is a sectional view showing an exemplary sectional structure of a circuit region in a semiconductor memory device according to a first modification of the second embodiment.

FIG. 39 is a sectional view taken along the line XXXIX-XXXIX indicated in FIG. 38 and shows exemplary connections of interconnect layers in the semiconductor memory device according to the first modification of the second embodiment.

FIG. 40 is a sectional view showing an exemplary sectional structure of a circuit region in a semiconductor memory device according to a second modification of the second embodiment.

FIG. 41 is a sectional view taken along the line XLI-XLI indicated in FIG. 40 and shows exemplary connections of interconnect layers in the semiconductor memory device according to the second modification of the second embodiment.

FIG. 42 is a sectional view showing an exemplary sectional structure of a circuit region in a semiconductor memory device according to a third modification of the second embodiment.

FIG. 43 is a sectional view taken along the line XLIII-XLIII indicated in FIG. 42 and shows exemplary connections of interconnect layers in the semiconductor memory device according to the third modification of the second embodiment.

FIG. 44 is a sectional view showing an exemplary sectional structure of a circuit region in a semiconductor memory device according to a fourth modification of the second embodiment.

FIG. 45 is a sectional view showing an exemplary sectional structure of a circuit region in a semiconductor memory device according to a fifth modification of the second embodiment.

FIG. 46 is a sectional view showing an exemplary sectional structure of a circuit region in a semiconductor memory device according to a sixth modification of the second embodiment.

### DETAILED DESCRIPTION

In general, according to one embodiment, a semiconductor memory device includes: a first chip including a substrate defining a first region and a second region; and a second chip contacting the first chip in a first direction crossing a surface of the substrate, the second chip being electrically connected to the first chip via a plurality of connection pads at a boundary region between the first chip and the second chip, the second chip including a memory cell array in the first region, the memory cell array including a source line, a plurality of word lines mutually separated in the first direction below the source line, and a memory pillar extending in the first direction, crossing the word lines, and including an upper end coupled to the source line, a plurality of contacts in the second region, the contacts extending in the first direction and each electrically connected to one of the connection pads, a conductor pattern contacting upper ends of the contacts, and a first interconnect extending above the conductor pattern and electrically connected to the conductor pattern.

Embodiments will be described with reference to the drawings. The drawings use dimensions, ratios, etc., which may not necessarily conform to actual products. The description will use the same reference signs for the elements or components having the same or substantially the same functions and configurations. To distinguish between elements having the same or substantially the same configurations, the description may add mutually different characters or numerals after their respective reference signs.

### 1 First Embodiment

A semiconductor memory device 1 according to a first embodiment will be described.

### 1.1 Configurations

Configurations for the semiconductor memory device 1 according to the first embodiment will be described.

### 1.1.1 Memory System

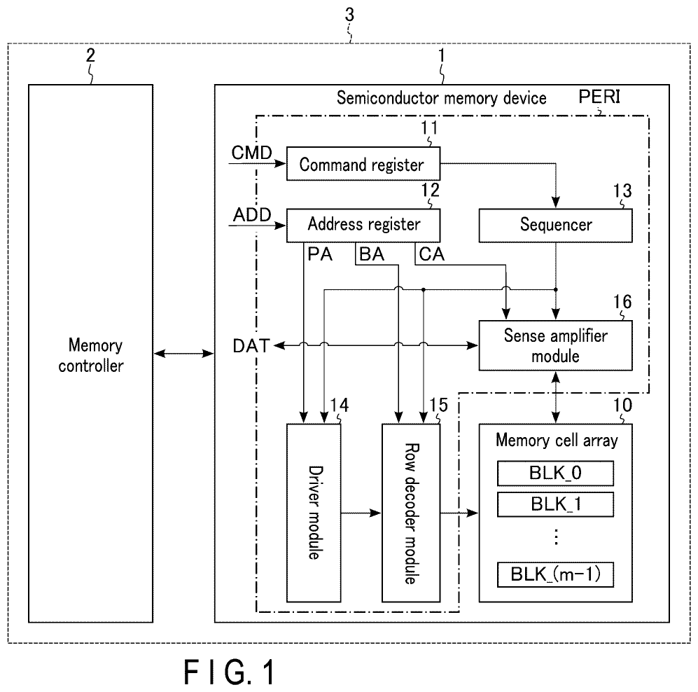

The description starts with an exemplary configuration of a memory system 3 by referring to FIG. 1. FIG. 1 is a block diagram showing an exemplary configuration of the memory system 3 including the semiconductor memory device 1 according to the first embodiment.

The memory system 3 may be, for example, a solid state drive (SSD), an SD™ card, or the like. In one example, the memory system 3 is adapted to be coupled to an external host device (not shown in the figure). The memory system 3 stores data from the host device. The memory system 3 also reads out data to the host device.

The memory system 3 includes the semiconductor memory device 1 and a memory controller 2.

The semiconductor memory device 1 may be, for example, a NAND flash memory. The semiconductor memory device 1 stores data in a nonvolatile manner. The description will assume instances where the semiconductor memory device 1 is a NAND flash memory.

The memory controller 2 is constituted by, for example, an integrated circuit such as a system-on-a-chip (SoC). The memory controller 2 writes data in the semiconductor memory device 1 based on, for example, a request from the host device. Also, the memory controller 2 reads data from the semiconductor memory device 1 based on, for example, a request from the host device. The memory controller 2 sends data read from the semiconductor memory device 1 to the host device.

Communications between the semiconductor memory device 1 and the memory controller 2 comply with, for example, a single data rate (SDR) interface, a toggle double data rate (DDR) interface, an open NAND flash interface (ONFI), etc.

### 1.1.2 Semiconductor Memory Device

Referring to the same FIG. 1, an internal configuration of the semiconductor memory device 1 will be described. In one example, the semiconductor memory device 1 includes a memory cell array 10 and a peripheral circuit PERI. In one example, the peripheral circuit PERI includes a command register 11, an address register 12, a sequencer 13, a driver module 14, a row decoder module 15, and a sense amplifier module 16.

The memory cell array 10 includes multiple blocks BLK0 to BLK(m−1), where m is an integer equal to or greater than 2. Each block BLK is a set of multiple memory cells capable of storing data in a nonvolatile manner. In one example, each block BLK is used as a unit for data erasure. The memory cell array 10 is provided with multiple bit lines and multiple word lines. In one example, each memory cell is associated with one bit line and one word line.

The command register 11 holds a command CMD received by the semiconductor memory device 1 from the memory controller 2. Examples of the command CMD include instructions to cause the sequencer 13 to conduct read, write, and erase operations, etc.

The address register 12 holds address information ADD received by the semiconductor memory device 1 from the memory controller 2. The address information ADD includes, for example, a page address PA, a block address BA, and a column address CA. The page address PA, the block address BA, and the column address CA in exemplary operations are used to select a word line, a block BLK, and a bit line, respectively.

The sequencer 13 takes total control over the operations of the semiconductor memory device 1. The sequencer 13 conducts read, write, and erase operations, etc., according to the command CMD held at the command register 11.

The driver module 14 generates voltages for use in the read, write, and erase operations, etc. For example, the driver module 14 applies the generated voltage to the signal line corresponding to a selected word line based on the page address PA held at the address register 12.

The row decoder module 15, based on the block address BA held at the address register 12, selects a single corresponding block BLK in the memory cell array 10. The row decoder module 15, for example, then transfers the voltage applied to the signal line corresponding to the selected word line to this selected word line in the selected block BLK.

The sense amplifier module 16 in a write operation transfers write data DAT received from the memory controller 2 to the memory cell array 10. Also, the sense amplifier module 16 in a read operation determines data stored in a memory cell based on the voltage of the corresponding bit line. The sense amplifier module 16 transfers the determination result to the memory controller 2 as read data DAT.

### 1.1.3 Circuit Configuration of Memory Cell Array

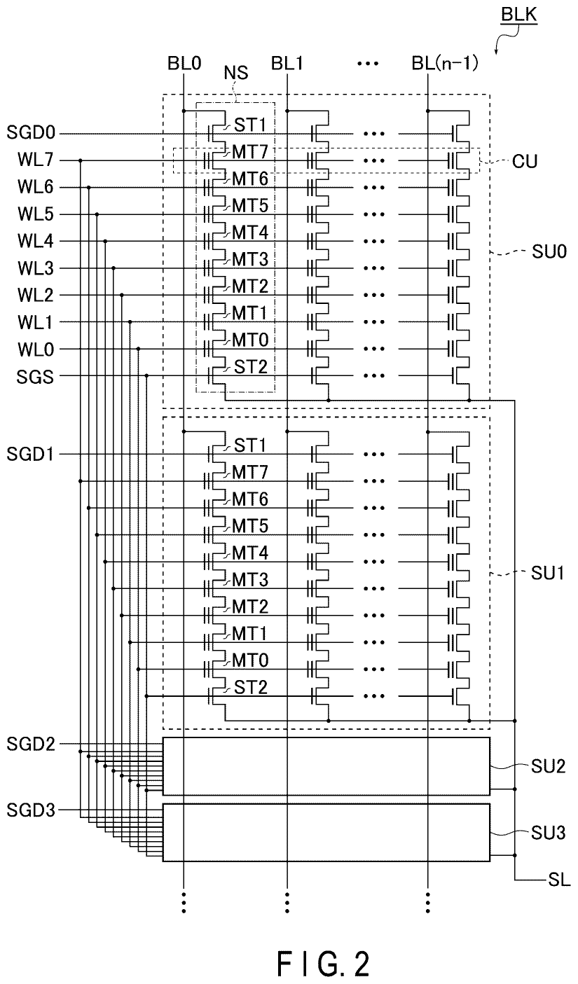

An exemplary circuit configuration of the memory cell array 10 will be described with reference to FIG. 2. FIG. 2 is a circuit diagram showing an exemplary circuit configuration of the memory cell array 10 in the semiconductor memory device 1 according to the embodiment. FIG. 2 shows one of the multiple blocks BLK included in the memory cell array 10. In the example shown in FIG. 2, the block BLK includes four string units SU0, SU1, SU2, and SU3.

Each string unit SU includes multiple NAND strings NS associated with respective bit lines BL0 to BL(n−1), where n is an integer equal to or greater than 2. In one example, the NAND strings NS each include memory cell transistors MT0 to MT7 and select transistors ST1 and ST2. The memory cell transistors MT0 to MT7 each include a control gate and a charge accumulating film. Each of the memory cell transistors MT0 to MT7 stores data in a nonvolatile manner. The select transistors ST1 and ST2 are used for the selection of the string unit SU in various operations. In the description below, each of the bit lines BL0 to BL(n−1) may be simply called a “bit line BL” if the context does not require discriminating the bit lines BL0 to BL(n−1) from one another. Also, each of the memory cell transistors MT0 to MT7 may be simply called a “memory cell MT” if the context does not require discriminating the memory cell transistors MT0 to MT7 from one another.

In each NAND string NS, the memory cell transistors MT0 to MT7 are coupled in series. The select transistor ST1 has its one end coupled to the bit line BL associated with the select transistor ST1. Another end of the select transistor ST1 is coupled to one end of a set of the memory cell transistors MT0 to MT7 coupled in series. The select transistor ST2 has its one end coupled to the other end of the set of the memory cell transistors MT0 to MT7 coupled in series. Another end of the select transistor ST2 is coupled to a source line SL.

In one block BLK, the memory cell transistors MT0 to MT7, with multiple of each provided, have their control gates coupled to respective word lines WL0 to WL7. The multiple select transistors ST1 in each of the string units SU0 to SU3 have their gates coupled to the respective and corresponding one of select gate lines SGD0 to SGD3. On the other hand, the gates of the multiple select transistors ST2 in the same block BLK are coupled to a common select gate line SGS. However, the embodiment is not limited to this, and the gates of the multiple select transistors ST2 may instead be coupled to different select gate lines SGS for the respective string units SU. In the description below, each of the word lines WL0 to WL7 may be simply called a “word line WL” if the context does not require discriminating the word lines WL0 to WL7 from one another. Also, each of the select gate lines SGD0 to SGD3 may be simply called a “select gate line SGD” if the context does not require discriminating the select gate lines SGD0 to SGD3 from one another.

The bit lines BL0 to BL(n−1) are assigned respective column addresses differing from one another. Each bit line BL is shared by the NAND strings NS having the same column address across the multiple blocks BLK. The word lines WL0 to WL7 are provided for each block BLK. In one example, the source line SL is shared by the multiple blocks BLK.

A set of multiple memory cell transistors MT coupled to the common word line WL within one string unit SU may also be called a “cell unit CU”. For example, the storage capacity of a cell unit CU constituted by multiple memory cell transistors MT each adapted to store 1-bit data is defined as “1-page data”. Each cell unit CU may have a storage capacity of 2-page data or more according to the bit number of data to be stored in its memory cell transistors MT.

Note that the circuit configuration of the memory cell array 10 is not limited to the above described configuration. For example, the number of string units SU in each block BLK may be discretionarily set. The numbers of the memory cell transistors MT and the select transistors ST1 and ST2 in each NAND string NS may also be discretionarily set.

### 1.1.4 Structure of Semiconductor Memory Device

An exemplary structure of the semiconductor memory device 1 according to the first embodiment will be described.

The description will assume that an X direction is substantially parallel to a semiconductor substrate of the semiconductor memory device 1. The X direction conforms to a direction in which the word lines WL extend. A Y direction is substantially parallel to the semiconductor substrate and is orthogonal to the X direction. The Y direction conforms to a direction in which the bit lines BL extend. A Z1 direction and a Z2 direction are both substantially perpendicular to the semiconductor substrate. The Z1 direction conforms to a direction from the semiconductor substrate of the semiconductor memory device 1 toward an electrode pad. The Z2 direction conforms to a direction from the electrode pad toward the semiconductor substrate. Each of the Z1 direction and the Z2 direction may be simply called a “Z direction” if the context does not require discriminating the Z1 direction and the Z2 direction from one another. In the following description, a side in the Z1 direction with respect to a given element or component may be called “one Z-direction side” (or simply “one side”), and a side in the Z2 direction with respect to a given element or component may be called “the other Z-direction side” (or simply “the other side”). Also, a surface of a given element or component that is located on the electrode pad side may be called a “first surface”, and a surface of a given element or component that is located on the semiconductor substrate side may be called a “second surface”. Such first and second surfaces may also be called “one Z-direction surface” and “the other Z-direction surface”, respectively.

### 1.1.4.1 Planar Configuration of Semiconductor Memory Device

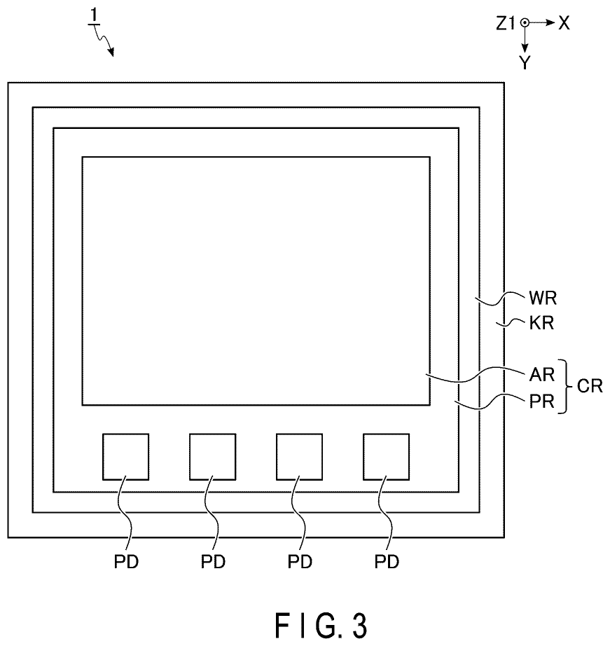

An exemplary planar configuration of the semiconductor memory device 1 will be described with reference to FIG. 3. FIG. 3 is a plan view showing an exemplary planar layout of the semiconductor memory device 1 according to the first embodiment.

The semiconductor memory device 1 in the planar layout shown in FIG. 3 is divided into a circuit region PR, a wall region WR, and a kerf region KR. Here, the circuit region CR is divided into an array region AR and a peripheral region PR.

The circuit region CR is provided with elements or components constituting the semiconductor memory device 1 which include, for example, the memory cell array 10, the command register 11, the address register 12, the sequencer 13, the driver module 14, the row decoder module 15, and the sense amplifier module 16. The memory cell array 10 is arranged in the array region AR in the circuit region CR. One or more electrode pads PD are further provided in the peripheral region PR. In one example, each electrode pad PD is exposed at the surface of the semiconductor memory device 1 and functions as a connection pad for coupling with a device, etc., external to the semiconductor memory device 1. In one example, the circuit region CR is a quadrilateral region.

The wall region WR in one example surrounds the outer periphery of the circuit region CR. The wall region WR includes, for example, one or more sealing portions (not shown in the figure) surrounding the outer periphery of the circuit region CR as viewed from above. The sealing portions function as, for example, a crack stopper, an edge seal, etc.

In one example, the kerf region KR surrounds the outer periphery of the wall region WR. The kerf region KR is located in the outermost periphery of the semiconductor memory device 1. The kerf region KR includes, for example, one or more alignment marks for use in the manufacture of the semiconductor memory device 1, a circuit or the like for the performance test of the semiconductor memory device 1, and so on.

### 1.1.4.2 Structure of Memory Cell Array

First, an exemplary structure of the memory cell array 10 arranged in the array region AR in the circuit region CR will be described.

### 1.1.4.2.1 Overall Configuration of Memory Cell Array

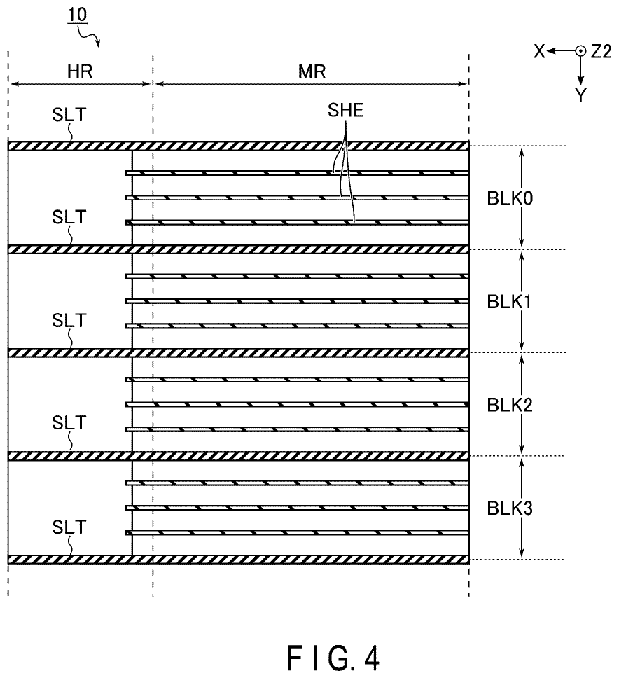

An overall configuration of the memory cell array 10 will be described with reference to FIG. 4. FIG. 4 is a plan view showing an exemplary planar layout of the memory cell array 10 in the semiconductor memory device 1 according to the first embodiment. FIG. 4 covers a part corresponding to four blocks BLK0 to BLK3.

The memory cell array 10 includes a stacked interconnect structure and multiple members SLT and SHE. The stacked interconnect structure includes the select gate lines SGD and SGS and the multiple word lines WL. The stacked interconnect structure is a structural component in which layers are stacked in the Z direction according to the staking number of the select gate lines SGD and SGS and the multiple word lines WL. In the following description, the select gate lines SGD and SGS and the multiple word lines WL may also be collectively called “stacked interconnects”.

In one example, the stacked interconnect structure is disposed over a memory region MR and a hookup region HR in the X direction.

The memory region MR refers to a region where data storage substantially takes place.

The hookup region HR refers to a region used for coupling between the stacked interconnects and the peripheral circuit PERI including the row decoder module 15, etc.

The members SLT each extend in the X direction. Each member SLT traverses the stacked interconnect structure throughout the memory region MR and the hookup region HR in the X direction. In one example, each member SLT has a structure filled with an insulator and a plate conductor (an occluded structure). Each member SLT is provided so that the stacked interconnects are split into portions next to each other via this member SLT. Each region delimited by the multiple members SLT corresponds to one block BLK. In the following description, an end portion of the blocks BLK0 to BLK3 that is on the block BLK0 side in the Y direction may be called “one Y-direction end”. Also, an end portion of the blocks BLK0 to BLK3 that is on the block BLK3 side in the Y direction may be called “the other Y-direction end”.

The members SHE each extend in the X direction. The first embodiment assumes the form where there are three members SHE arranged in every interval between the members SLT next to each other. Each member SHE traverses the stacked interconnect structure throughout the memory region MR in the X direction. In one example, each member SHE has an insulator-filled structure. In one example, each member SHE is provided so that the select gate lines SGD separate from each other and next to each other via this member SHE are formed. Each region delimited by applicable ones of the members SLT and SHE corresponds to one string unit SU.

In one example, the memory cell array 10 repeats the planar layout shown in FIG. 4 in the Y direction.

Note that the memory cell array 10 is not limited to the planar layout described above. For example, the number of members SHE arranged between the neighboring members SLT may be discretionarily set according to the number of string units SU.

### 1.1.4.2.2 Structure of Memory Cell Array in Memory Region

A structure of the memory cell array 10 in the memory region MR will be described.

### 1.1.4.2.2.1 Planar Structure

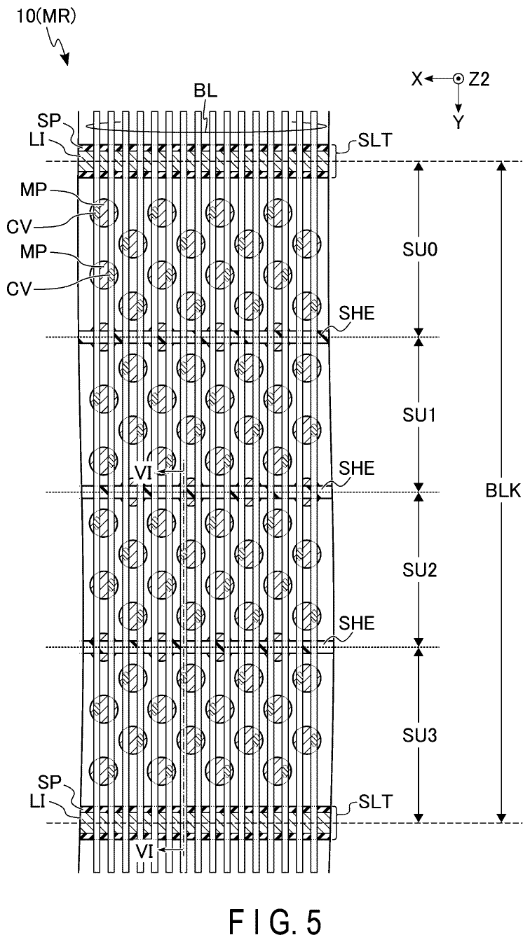

A planar structure of the memory cell array 10 in the memory region MR will be described with reference to FIG. 5. FIG. 5 is a plan view showing an exemplary planar layout of the memory cell array 10 in the semiconductor memory device 1 according to the first embodiment.

In the memory region MR, the memory cell array 10 includes multiple memory pillars MP, multiple contacts CV, and multiple bit lines BL. Each member SLT includes a core portion LI and spacers SP.

The memory pillars MP each function as, for example, an individual NAND string NS. In one example, these multiple memory pillars MP are arranged in a pattern of nineteen staggered rows in a region between two neighboring members SLT. Here, in one example, the memory pillars MP in the fifth row, the tenth row, and the fifteenth row from the one Y-direction end each overlap one respective member SHE.

The multiple bit lines BL each extend in the Y direction. Also, the multiple bit lines BL are arranged in the X direction. Each bit line BL overlaps at least one memory pillar MP for each string unit SU. In the example shown in FIG. 5, each bit line BL overlaps two memory pillars MP for each string unit SU. Of the multiple bit lines BL overlapping the same memory pillar MP, one of the bit lines BL is electrically connected to this memory pillar MP via a contact CV. In one example, there is no contact CV between each memory pillar MP that overlaps the member SHE and the bit lines BL. In other words, the memory pillars MP that overlap the member SHE are not electrically connected to the bit lines BL.

The core portion LI is a conductor extending in the X direction. The spacers SP are insulators each provided on the respective side surface of the core portion LI. The core portion L1 is sandwiched between the spacers SP. The core portion LI and the stacked interconnects located next to the core portion LI in the Y direction are electrically separated from each other by the corresponding spacer SP. As such, the core portion LI and the stacked interconnects next to the core portion LI in the Y direction are electrically insulated from each other.

### 1.1.4.2.2.2 Sectional Structure

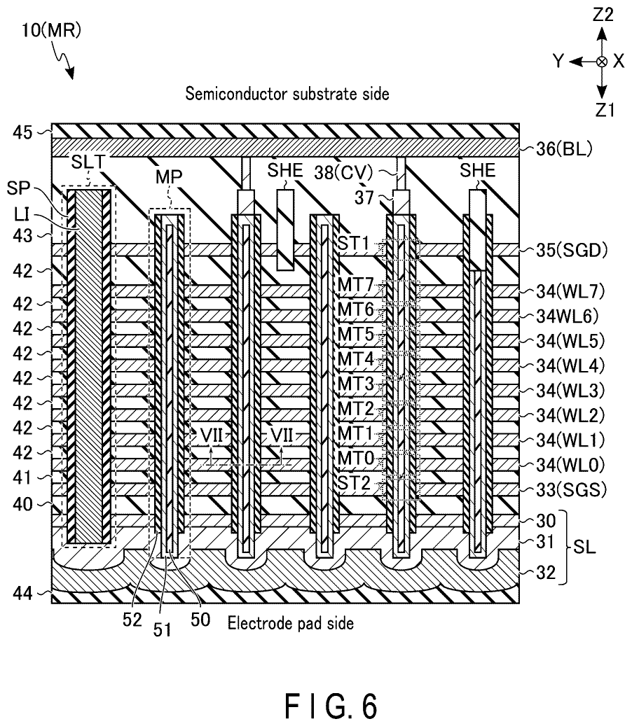

A sectional structure of the memory cell array 10 in the memory region MR will be described with reference to FIG. 6. FIG. 6 is a sectional view taken along the line VI-VI indicated in FIG. 5 and shows an exemplary sectional structure of the memory cell array 10 in the semiconductor memory device 1 according to the first embodiment.

The memory cell array 10 here includes conductor layers 30, 31, 32, 33, and 35, conductor layers 34, 36, 37, and 38 with multiple of each provided, insulator layers 40, 41, 43, 44, and 45, and multiple insulator layers 42. FIG. 6 shows five memory pillars MP among the multiple memory pillars MP. Also, FIG. 6 assumes a form where eight conductor layers 34 and eight insulator layers 42 are included as the multiple conductor layers 34 and the multiple insulator layers 42. The memory cell array 10 is provided between the electrode pad PD and the semiconductor substrate of the semiconductor memory device 1 in the Z direction.

In one example, the conductor layer 30 has a plate shape extending over the X-Y plane. The conductor layer 30 is made of a conductive material. The conductive material may be, for example, an impurity-added N-type semiconductor.

The conductor layer 31 is provided on the first surface of the conductor layer 30. The conductor layer 31 is made of a conductive material. This conductive material may be, for example, a doped polysilicon to which an N-type impurity has been added. The conductor layer 31 is, as will be explained later, formed on the first surfaces of the conductor layer 30 and the multiple memory pillars MP. Accordingly, the first surface of the conductor layer 31 in one example has a dent and rise profile corresponding to the multiple memory pillars MP. That is, the conductor layer 31 may have a non-flat first surface.

The conductor layer 32 is provided on the first surface of the conductor layer 31. The conductor layer 32 is made of a conductive material. This conductive material contains, for example, at least one of tungsten, aluminum, titanium, and/or titanium nitride. As will be explained later, the conductor layer 32 is formed on the first surface of the conductor layer 31. Accordingly, the first surface of the conductor layer 32 in one example has a dent and rise profile corresponding to the multiple memory pillars MP, similar to the profile of the first surface of the conductor layer 31. Thus, the conductor layer 32 may have a non-flat first surface as in the case of the conductor layer 31.

The conductor layers 30, 31, and 32 provided as described above function as the source line SL.

The insulator layer 40 is stacked on the second surface of the conductor layer 30. The conductor layer 33 is stacked on the second surface of the insulator layer 40. In one example, the conductor layer 33 has a plate shape extending over the X-Y plane. The conductor layer 33 is used as the select gate line SGS. The conductor layer 33 contains, for example, tungsten.

The insulator layer 41 is stacked on the second surface of the conductor layer 33. On the second surface of the insulator layer 41, the eight conductor layers 34 and the eight insulator layers 42 are stacked toward the Z2 direction in the order of the conductor layer 34, the insulator layer 42, . . . , the conductor layer 34, and the insulator layer 42. In one example, the conductor layer 34 has a plate shape extending over the X-Y plane. The eight conductor layers 34, one by one toward the Z2 direction, are used as the respective word lines WL0 to WL7. The conductor layers 34 each contain, for example, tungsten.

The conductor layer 35 is stacked on the second surface of the insulator layer 42 that is on the farthest other Z-direction side among the eight insulator layers 42. In one example, the conductor layer 35 has a plate shape extending over the X-Y plane. The conductor layer 35 is used as the select gate line SGD. The conductor layer 35 contains, for example, tungsten. In one example, the conductor layer 35 is electrically insulated for each string unit SU by the multiple members SHE.

The insulator layer 43 is stacked on the second surface of the conductor layer 35. The multiple conductor layers 36 are stacked on the second surface of the insulator layer 43. The conductor layers 36 each extend in the Y direction. FIG. 6 shows one of the multiple conductor layers 36. The conductor layers 36 function as the respective bit lines BL. The multiple conductor layers 36 are electrically connected to the multiple memory pillars MP via the multiple conductor layers 37 and 38.

The stacked structure including the conductor layers 30 to 33 and 35, the conductor layers 34 and 36 to 38 with multiple of each provided, the insulator layers 40, 41, and 43, and the multiple insulator layers 42 as described above is provided in such an arrangement that it is covered by insulators. FIG. 6 shows the insulator layer 44 which contacts the first surface of the conductor layer 32, and the insulator layer 45 which contacts the second surface of the conductor layer 36. Note that, although not illustrated in FIG. 6, the conductor layer 32 is, as will be described later, electrically connected to the peripheral circuit PERI via a conductor layer which is provided on the one side from the conductor layer 32. In one example, also, although not illustrated in FIG. 6, the multiple conductor layers 36 are, as will be described later, electrically connected to the peripheral circuit PERI via a conductor layer which is provided on the other side from the conductor layers 36.

The multiple memory pillars MP extending in the Z direction are provided on the one side from the multiple conductor layers 36. These memory pillars MP penetrate through the conductor layers 30, 33, and 35, and the multiple conductor layers 34.

In one example, the memory pillars MP each include a core member 50, a semiconductor film 51, and a stacked film 52. The core member 50 extends in the Z direction. The semiconductor film 51 surrounds the core member 50. The semiconductor film 51 contacts the conductor layer 31. The stacked film 52 covers the side surface of the semiconductor film 51 except a portion where the semiconductor film 51 and the conductor layer 31 are in contact with each other. The core member 50 contains, for example, an insulator such as silicon oxide. The semiconductor film 51 contains, for example, silicon. The configuration of the stacked film 52 will be described later.

The conductor layers 37 are each provided on the second surface of the corresponding semiconductor film 51. In one example, each conductor layer 37 functions as a columnar contact. The conductor layers 38 are each provided on the second surface of the corresponding conductor layer 37. In one example, each conductor layer 38 functions as the contact CV. With the configuration described above, the conductor layers 37 and 38 couple the applicable semiconductor film 51 and conductor layer 36 together. One conductor layer 36 is coupled with one conductor layer 37 and with one conductor layer 38 for each of the regions delimited by the members SLT and SHE.

In one example, each member SLT splits a set of the conductor layers 30, 33, and 35 and the multiple conductor layers 34. The core portion LI in the member SLT is provided along the member SLT. The second surface of the core portion LI is located between the conductor layer 35 and the conductor layers 36. In one example, the first surface of the core portion LI is located between the conductor layer 30 and the insulator layer 44. The spacers SP are each provided between the core portion LI and a set of the conductor layers 33 and 35 and the multiple conductor layers 34. By the presence of the spacers SP, the core portion LI is separated and electrically insulated from the conductor layers 30, 31, 33, and 35 and the multiple conductor layers 34. Note that, while not illustrated in FIG. 6, the core portion LI may include a barrier metal. More specifically, and for example, the core portion LI may have a structure constituted by a conductive member which contains metal such as tungsten and of which first surface and side surface are covered by the barrier metal. Also, the core portion LI may instead be formed of a semiconductor member, or the member SLT may in its entirety have a structure filled with the same insulator as that of the spacers SP.

A portion where each of the multiple memory pillars MP intersects the conductor layer 33 functions as the respective select transistor ST2. Portions where each of the multiple memory pillars MP intersects the multiple conductor layers 34 function as the memory cell transistors MT, respectively. A portion where each of the multiple memory pillars MP intersects the conductor layer 35 functions as the respective select transistor ST1.

### 1.1.4.2.2.3 Sectional Structure of Memory Pillars

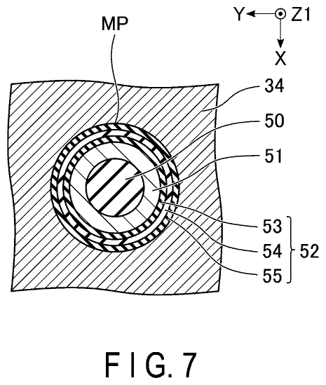

A structure of the memory pillars MP will be described with reference to FIG. 7. FIG. 7 is a sectional view taken along the line VII-VII indicated in FIG. 6 and shows an exemplary sectional structure of the memory pillar MP in the semiconductor memory device 1 according to the first embodiment.

The stacked film 52 includes a tunnel insulating film 53, a charge accumulating film 54, and a block insulating film 55. The tunnel insulating film 53 covers the side surface of the semiconductor film 51 except a portion where the semiconductor film 51 and the conductor layer 31 are in contact with each other. The charge accumulating film 54 covers the side surface of the tunnel insulating film 53. The block insulating film 55 covers the side surface of the charge accumulating film 54.

The tunnel insulating film 53 and the block insulating film 55 both contain, for example, silicon oxide. The charge accumulating film 54 contains, for example, silicon nitride. The charge accumulating film 54 is adapted to accumulate electric charges.

In the configuration as above, the semiconductor film 51 functions as a channel of each of the memory cell transistors MT0 to MT7 and the select transistors ST1 and ST2. Also, the charge accumulating film 54 has a function of holding an amount of electric charge corresponding to the data stored in the corresponding memory cell transistor MT. The semiconductor memory device 1 places each of the memory cell transistors MT0 to MT7 and the select transistors ST1 and ST2 into an ON state so as to cause a current to flow between the source line SL and the respective bit line BL through the memory pillar MP and the conductor layers 37 and 38.

### 1.1.4.3 Overall Sectional Structure of Semiconductor Memory Device

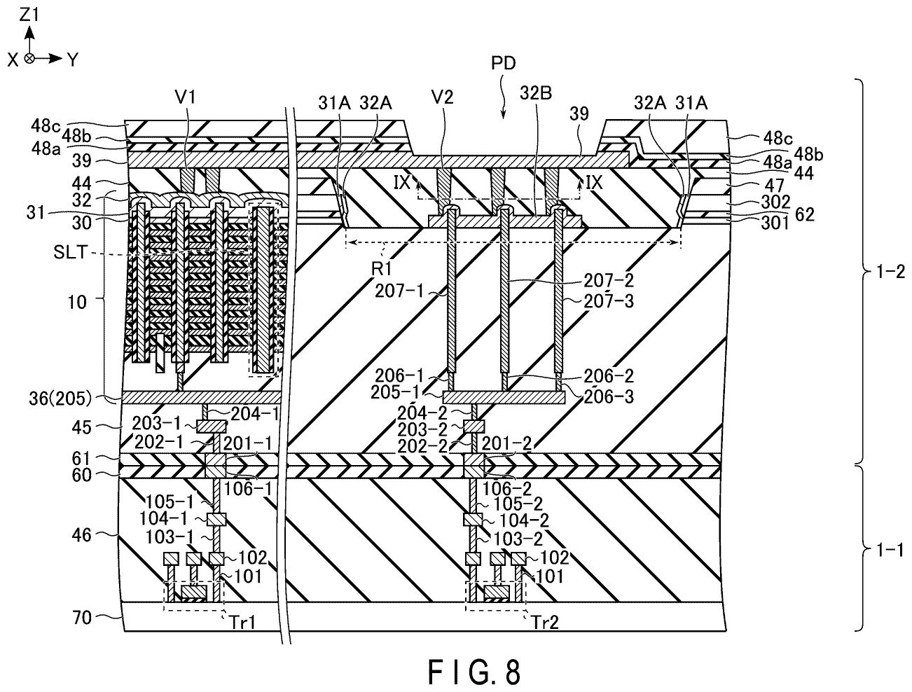

An overall sectional structure of the semiconductor memory device 1 will be described with reference to FIG. 8. FIG. 8 is a sectional view showing an exemplary sectional structure of the circuit region CR in the semiconductor memory device 1 according to the first embodiment. What is shown in FIG. 8 is a sectional structure of a portion of the semiconductor memory device 1.

The semiconductor memory device 1 has a structure including a circuit chip 1-1 and a memory chip 1-2 bonded together.

### 1.1.4.3.1 Circuit Chip

A sectional structure of the circuit chip 1-1 will be described first.

In one example, the circuit chip 1-1 includes a semiconductor substrate 70, multiple conductor layers 101, 102, 103, 104, 105, and 106 forming a portion of the peripheral circuit PERI, and insulator layers 46 and 60. The semiconductor substrate 70 is constituted by, for example, an impurity-added P-type semiconductor.

In one example, the multiple conductor layers 101 to 106 each function as a columnar contact or an interconnect. The multiple conductor layers 103 include conductor layers 103-1 and 103-2. The multiple conductor layers 104 include conductor layers 104-1 and 104-2. The multiple conductor layers 105 include conductor layers 105-1 and 105-2. The multiple conductor layers 106 include conductor layers 106-1 and 106-2.

The insulator layer 46 is provided on the first surface of the semiconductor substrate 70. The insulator layer 46 contains, for example, silicon oxide. The multiple conductor layers 101, 102, 103, 104, and 105 are formed within the insulator layer 46.

The peripheral circuit PERI is provided on the first surface of the semiconductor substrate 70 in the circuit region CR. FIG. 8 shows transistors Tr1 and Tr2 as exemplary components included in the peripheral circuit PERI. In the following description, each of the transistors Tr1 and Tr2 may be simply called a “transistor Tr” if the context does not require discriminating the transistors Tr1 and Tr2 from one another. Each transistor Tr includes a gate insulating film, a gate electrode, and a source and a drain (not shown in the figure) formed in the semiconductor substrate 70.

The multiple conductor layers 101 are provided on the first surfaces of the gate electrode, the source, and the drain of the transistor Tr1, as well as on the first surfaces of the gate electrode, the source, and the drain of the transistor Tr2, respectively. The multiple conductor layers 102 are coupled to the first surfaces of the multiple conductor layers 101, respectively.

The multiple conductor layers 103 are each coupled to the first surface of the applicable one of the multiple conductor layers 102. The conductor layers 103-1 and 103-2 are electrically connected to the respective transistors Tr1 and Tr2.

The conductor layers 104-1 and 104-2 are coupled to the first surfaces of the conductor layers 103-1 and 103-2, respectively.

The conductor layers 105-1 and 105-2 are coupled to the first surfaces of the conductor layers 104-1 and 104-2, respectively. The multiple conductor layers 105 are provided so that their respective first surfaces are flush with the first surface of the insulator layer 46.

The insulator layer 60 is provided on the first surfaces of the insulator layer 46 and the multiple conductor layers 105. The insulator layer 60 contains, for example, silicon oxide.

The multiple conductor layers 106 are provided at the same layer level as the insulator layer 60. The conductor layers 106-1 and 106-2 are coupled to the first surfaces of the conductor layers 105-1 and 105-2, respectively. The multiple conductor layers 106 are provided so that their respective first surfaces are flush with the first surface of the insulator layer 60. The multiple conductor layers 106 each contain, for example, copper. The multiple conductor layers 106 function as multiple connection pads for making electrical connection between the circuit chip 1-1 and the memory chip 1-2. The connection pads may also be called “bonding pads”.

### 1.1.4.3.2 Memory Chip

Referring to the same FIG. 8, a sectional structure of the memory chip 1-2 will be described.

The memory chip 1-2 includes, in one example, multiple conductor layers 201, 202, 203, 204, 205, 206, and 207, a conductor layer 39, insulator layers 44, 45, 47, 48a, 48b, 48c, 61, and 62, semiconductor layers 301 and 302, multiple coupling portions V1 and V2, and the memory cell array 10.

In one example, the multiple conductor layers 201 to 207 each function as a columnar contact or an interconnect. The multiple conductor layers 201 include conductor layers 201-1 and 201-2. The multiple conductor layers 202 include conductor layers 202-1 and 202-2. The multiple conductor layers 203 include conductor layers 203-1 and 203-2. The multiple conductor layers 204 include conductor layers 204-1 and 204-2. The multiple conductor layers 205 include conductor layers 36 (205) and 205-1. The multiple conductor layers 206 include conductor layers 206-1, 206-2, and 206-3. The multiple conductor layers 207 include conductor layers 207-1, 207-2, and 207-3.

The insulator layer 61 in the memory chip 1-2 is provided on the first surface of the circuit chip 1-1. The insulator layer 61 contains, for example, silicon oxide.

The multiple conductor layers 201 are provided at the same layer level as the insulator layer 61. The conductor layers 201-1 and 201-2 are coupled to the first surfaces of the conductor layers 106-1 and 106-2, respectively. The multiple conductor layers 201 are provided so that their respective second surfaces are flush with the second surface of the insulator layer 61. The multiple conductor layers 201 each contain, for example, copper. The multiple conductor layers 201 function as multiple connection pads for making electrical connection between the circuit chip 1-1 and the memory chip 1-2. With the configuration described above, the circuit chip 1-1 and the memory chip 1-2 are electrically connected to each other via the multiple conductor layers 106 and 201.

The insulator layer 45 is provided on the first surfaces of the insulator layer 61 and the multiple conductor layers 201. The multiple conductor layers 202 to 206, portions of the multiple conductor layers 207, and a portion of the memory cell array 10 are formed within the insulator layer 45.

The memory cell array 10 is formed in such an arrangement that the conductor layer 32 is located on the one Z-direction side and the conductor layer 36 (205) is located on the other Z-direction side.

The conductor layer 202-1 is provided on the first surface of the conductor layer 201-1. The conductor layer 203-1 is coupled to the first surface of the conductor layer 202-1. The conductor layer 204-1 is coupled to the first surface of the conductor layer 203-1. The conductor layer 204-1, through its first surface, is coupled to the conductor layer 36 (205). With the above configuration, the conductor layer 36 and the transistor Tr1 are made capable of being coupled to each other. In other words, the bit line BL of the memory cell array 10 and the peripheral circuit PERI are electrically connected to each other.

The conductor layer 202-2 is provided on the first surface of the conductor layer 201-2. The conductor layer 203-2 is provided on the first surface of the conductor layer 202-2. The conductor layer 204-2 is provided on the first surface of the conductor layer 203-2. The conductor layer 205-1 is provided on the first surface of the conductor layer 204-2. The conductor layers 206-1, 206-2, and 206-3 are provided on the first surface of the conductor layer 205-1. The conductor layer 207-1 is provided on the first surface of the conductor layer 206-1. The conductor layer 207-1 extends in the Z direction. The conductor layer 207-1 includes, on the one side, a portion projecting from the insulator layer 45. In one example, the conductor layer 207-1 functions as a columnar contact.

The conductor layers 207-2 and 207-3 are provided on the first surfaces of the conductor layers 206-2 and 206-3, respectively, as with the conductor layer 206-1. The conductor layers 207-2 and 207-3, similar to the conductor layer 207-1, extend in the Z direction. Also, the conductor layers 207-2 and 207-3 each include, on the one side, a portion projecting from the insulator layer 45. In one example, the conductor layers 207-2 and 207-3 each function as a columnar contact. The conductor layers 207-1, 207-2, and 207-3 are electrically connected to the same conductor layer 201-2 via the conductor layer 205-1 in the insulator layer 45. Note that the conductor layers 207-1, 207-2, and 207-3 may instead be electrically connected to the conductor layer 201-2 in such a form that the connections are made via the common conductor layer 203-2 and further via multiple conductor layers 204 on the first surface of the conductor layer 203-2 and also multiple conductor layers 205, provided for the respective conductor layers 207-1, 207-2, and 207-3.

In one example, the semiconductor layer (pattern portion) 301 is provided on portions of the first surface of the insulator layer 45 that are other than the region of the memory cell array 10 and that are next to, and sandwich, a region R1 encompassing the positions where the multiple conductor layers 207 are provided. The semiconductor layer 301 and the conductor layer 30 in the memory cell array 10 are at the same layer level as each other. The insulator layer 62 is provided on the first surface of the semiconductor layer 301. The semiconductor layer 302 is provided on the first surface of the insulator layer 62. The semiconductor layers 301 and 302 are, for example, non-doped polysilicon. The semiconductor layers 301 and 302 are electrically insulated from the source line SL. The insulator layer 47 is provided on the first surface of the semiconductor layer 302. Due to the above configuration, the region R1 shown in FIG. 8 is sandwiched in the Y direction by two wall surfaces each constituted by the semiconductor layers 301 and 302 and the insulator layers 47 and 62.

In one example, the first surface of the insulator layer 45 in the region R1 is on the other side from the first surface of the insulator layer 45 in the regions next to the region R1 and other than the region of the memory cell array 10. In other words, the first surface of the insulator layer 45 in the region R1 is, for example, on the other side from the second surface of the semiconductor layer 301.

In the region R1, a conductor layer (conductor pattern) 32B is provided on a portion of the first surface of the insulator layer 45. The conductor layer 32B contacts the respective one-side portions of the multiple conductor layers 207 that project from the insulator layer 45. In one example, the conductor layer 32B is made of the same conductive material as that of the conductor layer 32. In one example, the conductor layer 32B is formed to have a pattern which extends over the X-Y plane in a plate shape. The conductor layer 32B embraces the one-side portions of the multiple conductor layers 207. In one example, the first surface of the conductor layer 32B has a dent and rise profile corresponding to the multiple conductor layers 207. That is, the conductor layer 32B may have a non-flat first surface. However, the first surface of the conductor layer 32B is not limited to this and may instead be flat.

The multiple coupling portions V1 are provided on the first surface of the conductor layer 32. The multiple coupling portions V1 are each formed of a conductive material. This conductive material contains, for example, tungsten. Note that, while FIG. 8 assumes an example where two coupling portions V1 are formed on the first surface of the conductor layer 32, no limitation is intended by this. The number of the coupling portions V1 may be set to any number as long as it is one or more.

The multiple coupling portions V2 are provided on the first surface of the conductor layer 32B. The multiple coupling portions V2 are each formed of a conductive material. This conductive material contains, for example, tungsten. Note that, while FIG. 8 assumes an example where three coupling portions V2 are formed on the first surface of the conductor layer 32B, no limitation is intended by this. The number of the coupling portions V2 may be set to any number as long as it is one or more.

The insulator layer (insulator portion) 44 is provided on a portion of the first surface of the insulator layer 45 that is in the region R1 and other than the portion where the conductor layer 32B is provided, on the first surface of the insulator layer 47, and also on portions of the first surfaces of the conductor layers 32 and 32B that are other than the portions where the multiple coupling portions V1 and V2 are provided. In one example, the insulator layer 44 has a first surface having a uniform height. The first surface of the insulator layer 44 is formed to be flush with the respective first surfaces of the multiple coupling portions V1 and V2. Note that, as will be described for a fourth modification of the first embodiment, the first surface of the insulator layer 44 may have a level difference.

On the two wall surfaces sandwiching the region R1 in the Y direction and constituted by the semiconductor layers 301 and 302 and the insulator layers 47 and 62, conductor layers 31A and 32A resulting from the later described formation of the conductor layers 31 and 32 may be provided. Note that, in one example, outside the part shown in FIG. 8, the region R1 is also sandwiched in the X direction by a configuration similar to the configuration in the Y direction. That is, in one example, the semiconductor memory device 1 includes two wall surfaces sandwiching the region R1 in the X direction and constituted by the semiconductor layers 301 and 302 and the insulator layers 47 and 62. These two wall surfaces may also be provided with the conductor layers 31A and 32A resulting from the later described formation of the conductor layers 31 and 32. Thus, as described above, the region R1 in one example is surrounded by four wall surfaces in top view. With the above configuration, the conductor layers 31A and 32A may be provided between each of the wall surfaces and the insulator layer 44. The conductor layers 31A and 32A may be provided partially or entirely over each wall surface.

In one example, the conductor layer 39 includes a portion provided in contact with the multiple coupling portions V1, namely, a portion provided on the first surfaces of the coupling portions V1 and on portions of the first surface of the insulator layer 44 that are around the respective coupling portions V1. The conductor layer 39 in one example also includes a portion provided in contact with the multiple coupling portions V2, namely, a portion provided on the first surfaces of the coupling portions V2 and on portions of the first surface of the insulator layer 44 that are around the respective coupling portions V2. The conductor layer 39 functions as an interconnect layer extending in the Y direction. The portion of the conductor layer 39 that contacts the multiple coupling portions V1 and the portion of the conductor layer 39 that contacts the multiple coupling portions V2 are provided at the same level. The conductor layer 39 contains, for example, aluminum.

In the configuration as described above, the multiple coupling portions V1 may each be regarded as a via that fills a space assumed between the portion of the conductor layer 39 that contacts the corresponding coupling portion V1 and the conductor layer 32. Also, the multiple coupling portions V2 may each be regarded as a via that fills a space assumed between the portion of the conductor layer 39 that contacts the corresponding coupling portion V2 and the conductor layer 32B.

The portion of the conductor layer 39 that contacts the multiple coupling portions V2 includes a region exposed at the first surface of the semiconductor memory device 1. In one example, this region forms the electrode pad PD for coupling with a device external to the semiconductor memory device 1. The electrode pad PD is provided at a position overlapping the region R1 in the Z direction. As such, the semiconductor layers 301 and 302 are not present in the region overlapping the electrode pad PD in the Z direction. In one example, the electrode pad PD is provided at a position which also at least partially overlaps the multiple coupling portions V2, the multiple conductor layers 207, and the conductor layer 32B in the Z direction. Here, the electrode pad PD in one example is provided in such a form that the area of the conductor layer 32B is smaller than the area of the electrode pad PD in the Z direction perspective.

With the above configuration, for example, the electrode pad PD and the transistor Tr2 can be coupled to each other via the conductor layers 32B, 101 to 106, and 201 to 207, and the multiple coupling portions V2. That is, the electrode pad PD and the peripheral circuit PERI are electrically connected to each other.

Note that, in one example, the portion (interconnect) of the conductor layer 39 that contacts the multiple coupling portions V1 and the portion (interconnect) of the conductor layer 39 that contacts the multiple coupling portions V2 are electrically separated from each other. In this form, while not shown in the figure, a configuration is adopted where the portion of the conductor layer 39 that contacts the multiple coupling portions V1 is coupled to the peripheral circuit PERI in the circuit chip 1-1 through elements or components similar to the conductor layers 201 to 207. With this configuration, the conductor layer 32 and the peripheral circuit PERI can be coupled to each other via the conductor layers 39, 101 to 106, and 201 to 207, and the multiple coupling portions V1. Note, however, that the above description does not pose limitations to the configuration, and although not shown in the figure, the portion of the conductor layer 39 that contacts the multiple coupling portions V1 and the portion of the conductor layer 39 that contacts the multiple coupling portions V2 may instead be coupled to each other.

On the one-side portion of the semiconductor memory device 1 excluding a portion where the electrode pad PD is provided, the insulator layers 48a, 48b, and 48c are stacked in this order in the Z direction. The insulator layer 48a in one example is an insulator containing silicon oxide, etc. The insulator layers 48b and 48c in one example contain silicon nitride, a resin material, etc. The insulator layers 48b and 48c in one example function as a passivation film.

### 1.1.4.3.3 Structure Around Multiple Coupling Portions V2

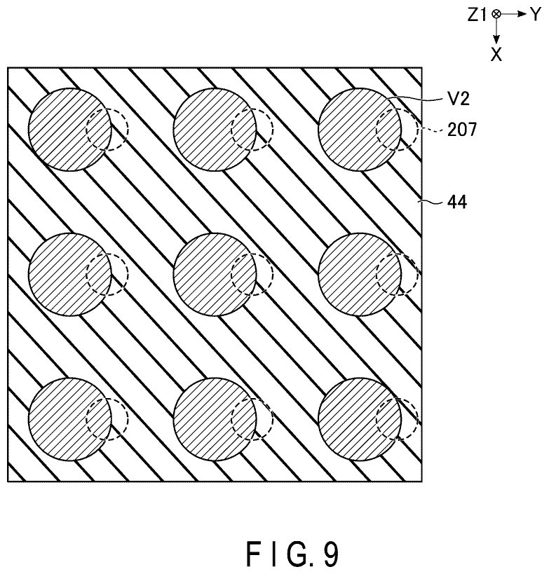

A structure around the multiple coupling portions V2 will be described to a further extent with reference to FIG. 9. FIG. 9 is a sectional view taken along the line IX-IX indicated in FIG. 8 and shows exemplary coupling portions between the interconnect layer and the respective contacts in the semiconductor memory device 1 according to the first embodiment.

In one example, the multiple conductor layers 207 functioning as respective contacts are arranged in a grid pattern in an X-Y cross-section. FIG. 9 shows a form where nine conductor layers 207 indicated by dashed lines are arranged in a 3×3 grid pattern. The multiple conductor layers 207 may each have an X-Y cross-section of a circular, quadrilateral, or other shape.

In one example, the multiple coupling portions V2 are arranged in a grid pattern in an X-Y cross section in a manner similar to the multiple conductor layers 207. FIG. 9 shows a form where, similarly to the multiple conductor layers 207, nine coupling portions V2 are arranged in a 3×3 grid pattern. The multiple coupling portions V2 may be arranged so that they either overlap the multiple conductor layers 207 or do not overlap the multiple conductor layers 207 in the Z direction. The multiple coupling portions V2 may each have an X-Y cross-section of a circular, quadrilateral, or other shape.

Note that, in each of the X direction and the Y direction, the intervals (pitches) at which the multiple coupling portions V2 are arranged and the intervals at which the multiple conductor layers 207 are arranged may be independently set.

### 1.1.4.3.4 Sectional Structure of Connection Pads

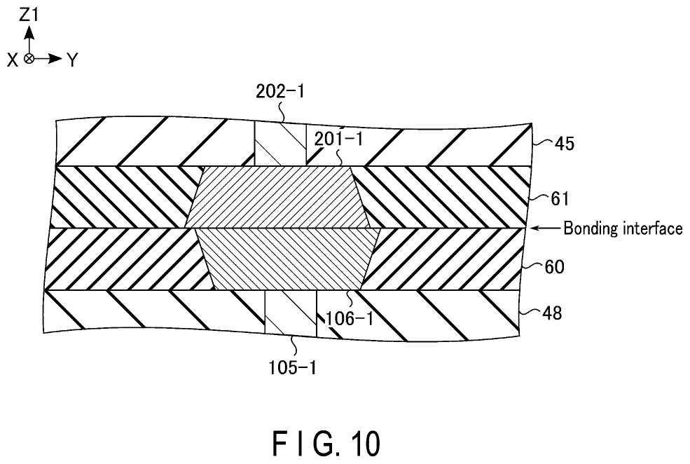

A sectional structure of the connection pads will be described with reference to FIG. 10. FIG. 10 is a sectional view showing an exemplary sectional structure of the connection pads in the semiconductor memory device 1 according to the first embodiment. The description will be given of a part where the conductor layer 106-1 and the conductor layer 201-1 are coupled to each other, and such a description is likewise applicable to the parts where the other multiple conductor layers 106 and their respective corresponding conductor layers 201 are coupled to each other.

In one example, the conductor layer 106-1 and the conductor layer 201-1 have comparable areas in the bonding interface where bonding between the circuit chip 1-1 and the memory chip 1-2 takes place. Assuming that the conductor layers 106-1 and 201-1 are both copper, the conductor layers 106-1 and 201-1 would be integrated and make recognition of the boundary between their copper difficult. Nevertheless, the bond state will be recognizable from, for example, deformations in shapes of the bonded conductor layers 106-1 and 201-1 that would occur due to misaligned bonding positions. Also, for example, the bond state will be recognizable from displaced barrier metals for copper. That is, the bond state can be recognized from inclusion of discontinuous portions in the side surface.

Note also that the conductor layers 106-1 and 201-1, if formed through a damascene method, each have tapered side surfaces. Thus, each side wall of the conductor layer 106-1 and each side wall of the conductor layer 201-1 do not together form a straight line. Accordingly, the Z direction cross-section of a portion where the conductor layers 106-1 and 201-1 are bonded to each other shows a non-rectangular profile.

In addition to the above, bonding of the conductor layers 106-1 and 201-1 produces a structure in which barrier metals cover the first, second, and side surfaces of the copper elements forming the conductor layers 106-1 and 201-1. On the other hand, general interconnect layers which employ copper are provided with an insulator layer (silicon nitride, nitrogen-containing silicon carbide, or the like) over the top surface of the copper so as to give an anti-copper-oxidation function, and no barrier metal is provided. Thus, it is possible to distinguish from general interconnect layers even if misalignment in bonding positions is not involved.

### 1.2 Method for Manufacturing Semiconductor Memory Device

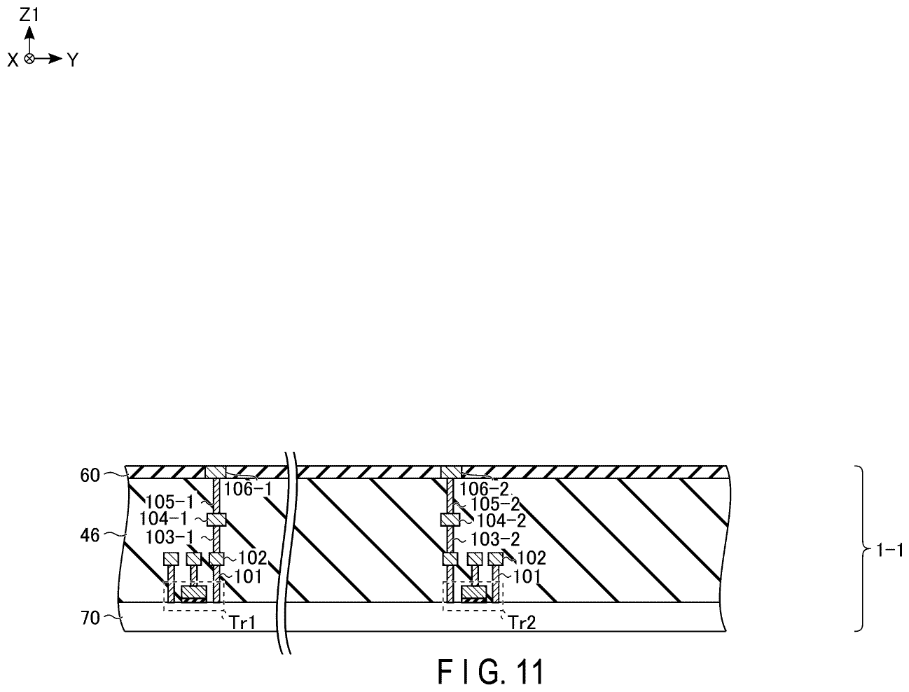

A method for manufacturing the semiconductor memory device 1 will be described with reference to FIGS. 11 to 20. FIGS. 11 to 20 are sectional views for explaining an exemplary method for manufacturing the semiconductor memory device 1 according to the first embodiment. The sectional views shown in FIGS. 11 to 20 each show a part corresponding to FIG. 8.

First, as shown in FIG. 11, elements included in the peripheral circuit PERI, such as the transistors Tr1 and Tr2, the multiple conductor layers 101 to 106, and the insulator layers 46 and 60, are formed on the semiconductor substrate 70. In other words, the circuit chip 1-1 is formed.

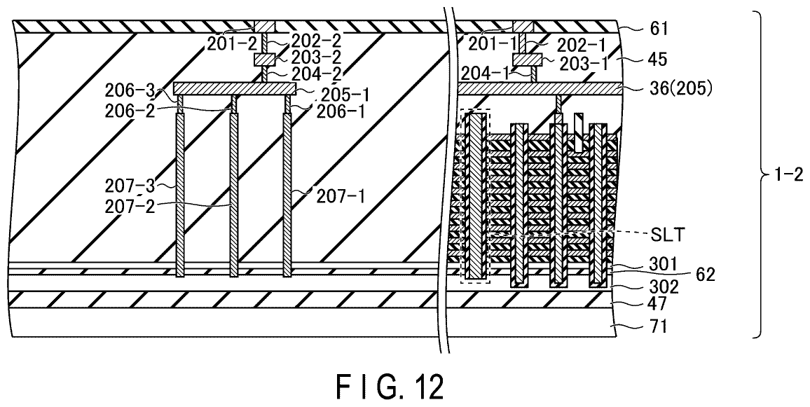

Next, as shown in FIG. 12, the insulator layer 47, the conductor layers 33 and 35, the multiple conductor layers 34 and 201 to 207, the semiconductor layers 301 and 302, the insulator layers 40, 41, 43, and 62, the multiple insulator layers 42, structural portions corresponding to the multiple memory pillars MP, the multiple members SLT and SHE, and the insulator layer 45 portion and the insulator layer 61 which cover these elements are formed on the second surface of a semiconductor substrate 71 formed of an impurity-added P-type semiconductor. In other words, a structure corresponding to the memory chip 1-2 is formed. Here, the semiconductor layers 301 and 302 and the insulator layers 47 and 62 are formed over the entire second surface of the semiconductor substrate 71.

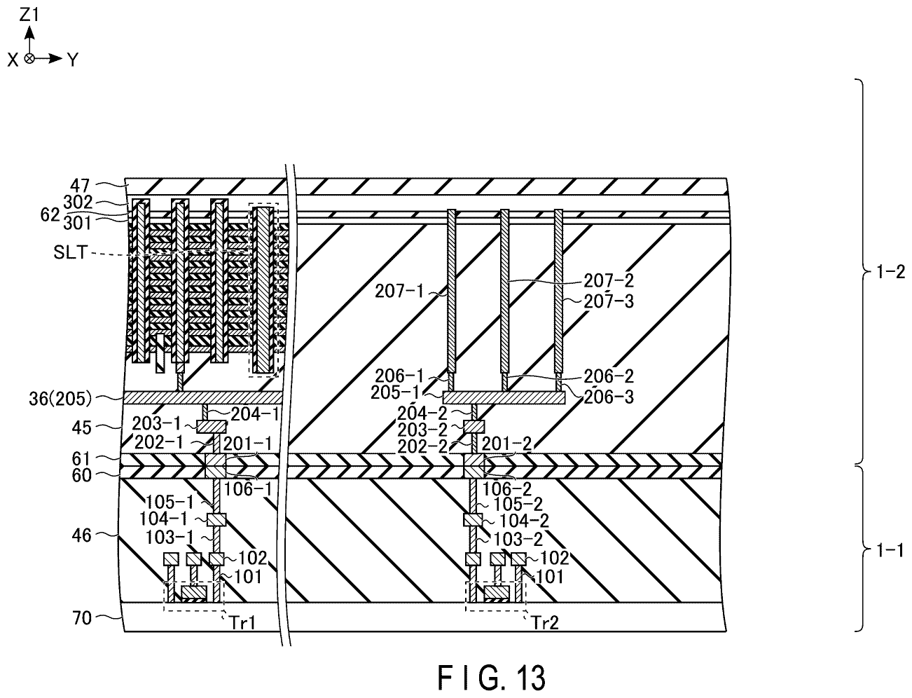

Then, as shown in FIG. 13, the circuit chip 1-1 and the structure corresponding to the memory chip 1-2 are bonded together by a bonding process. More specifically, the circuit chip 1-1 and the structure corresponding to the memory chip 1-2 are put in such an arrangement that the multiple conductor layers 106 functioning as the connection pads of the circuit chip 1-1 and the multiple conductor layers 201 functioning as the connection pads of the memory chip 1-2 face each other. The connection pads facing each other are joined together by a heat treatment. Subsequently, the semiconductor substrate 71 is removed by, for example, chemical mechanical polishing (CMP).

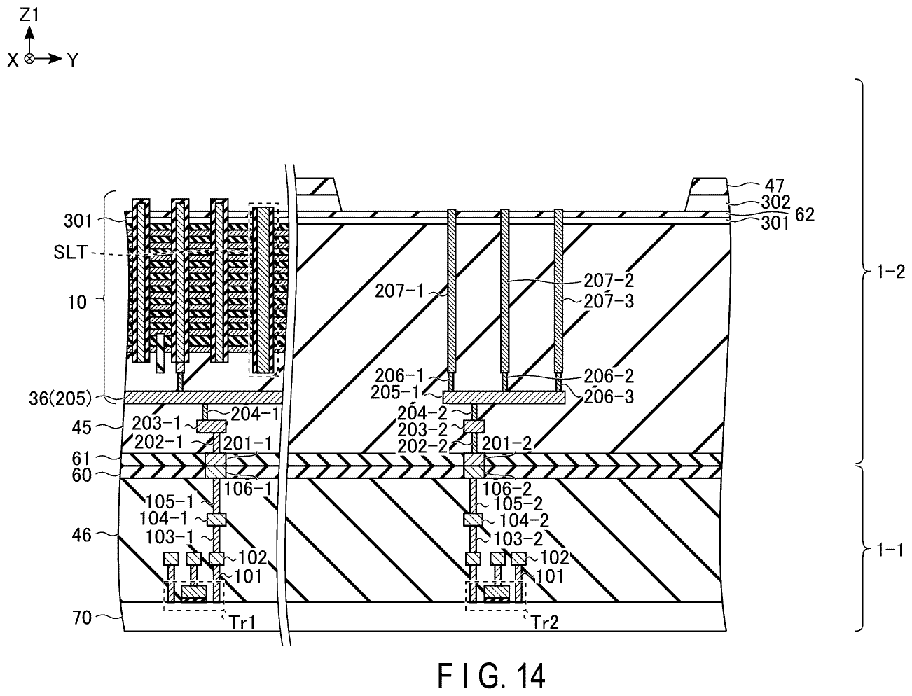

Then, as shown in FIG. 14, the insulator layer 47 and the semiconductor layer 302 in the locations corresponding to the memory cell array 10 and the region R1 are removed. In one example, removal of the portions corresponding to the memory cell array 10 and removal of the portions corresponding to the region R1 are conducted at the same time.

Also, in each memory pillar MP, a portion of the stacked film 52 that is located on the one side from the insulator layer 62 is removed. This exposes the semiconductor film 51 located on the one side from the insulator layer 62, at the surface. Also, the insulator layer 62 in the locations corresponding to the memory cell array 10 and the region R1 is removed. This exposes the semiconductor layer 301 at the portions of the surface that correspond to the memory cell array 10 and the region R1. Here, in the portion corresponding to the memory cell array 10, for example, the respective one-side portions of the multiple members SLT are also exposed at the surface. In the location corresponding to the region R1, for example, the respective one-side portions of the multiple conductor layers 207 are also exposed at the surface.

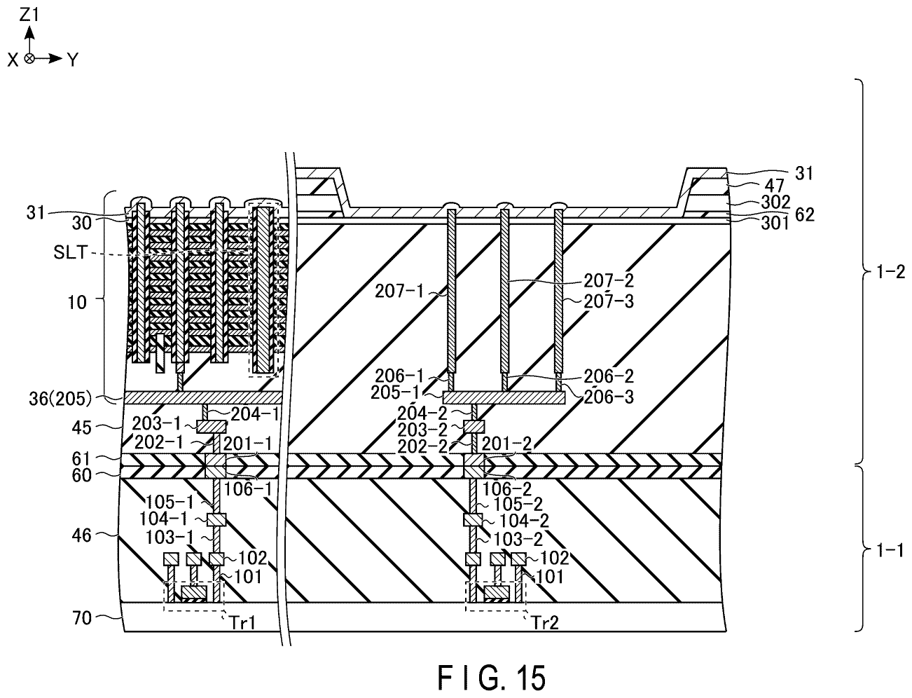

Next, as shown in FIG. 15, the conductor layer 31 is stacked on the surface-exposed portions of the first surface of the semiconductor layer 301, the surface-exposed portions of the memory pillars MP, the first surface of the insulator layer 47, the one-side portions of the multiple members SLT, and the one-side portions of the multiple conductor layers 207. Here, a portion of the semiconductor layer 301 that corresponds to the memory cell array 10 is turned into the conductor layer 30 by diffusion of impurity. More specifically, this step first includes formation of an amorphous silicon film on the surface-exposed portions of the first surface of the semiconductor layer 301, the surface-exposed portions of the memory pillars MP, the first surface of the insulator layer 47, the one-side portions of the multiple members SLT, and the one-side portions of the multiple conductor layers 207. Then, an impurity is injected into the formed amorphous silicon film, and processes such as a heat treatment are subsequently conducted so that the impurity is caused to diffuse across the semiconductor layer 301 and the formed amorphous silicon film is reformed into polysilicon. The conductor layers 30 and 31 are thus formed.

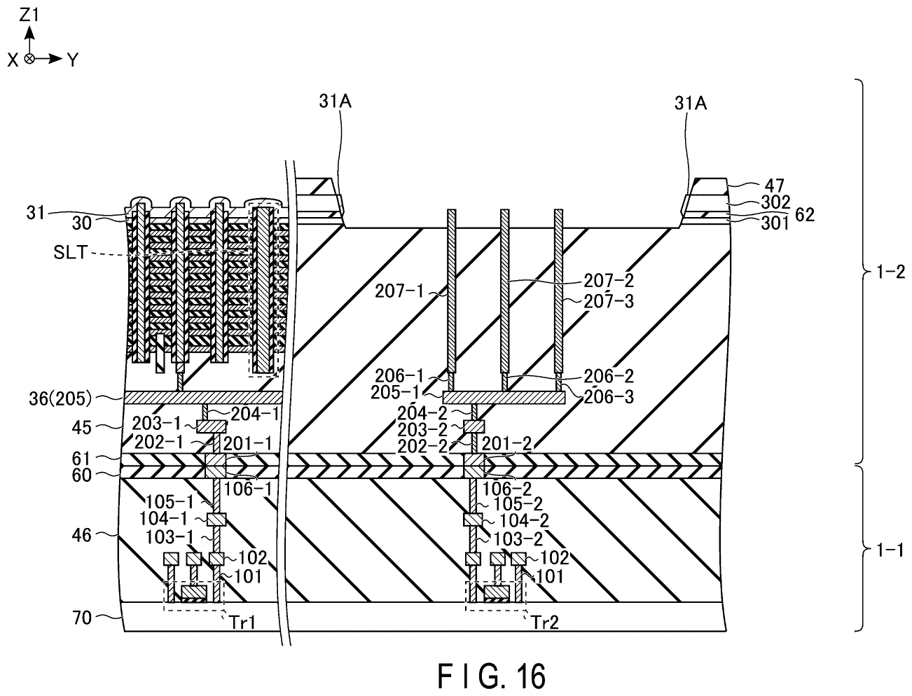

Then, etching or the like is conducted with a mask so that portions of the thus-formed conductor layer 31 that correspond to regions other than the memory cell array 10 are removed as shown in FIG. 16. Here, in the location corresponding to the region R1, the respective one-side portions of the semiconductor layer 301 and the insulator layer 45 are also removed. Accordingly, in the location corresponding to the region R1, for example, a portion of the first surface of the insulator layer 45 and the respective one-side portions of the multiple conductor layers 207 that project from the insulator layer 45 are exposed at the surface. Also, as a result of the above process, the conductor layer 31A, which is a trace of the conductor layer 31, is formed on the wall surfaces constituted by the semiconductor layers 301 and 302 and the insulator layers 47 and 62 as shown in FIG. 16.

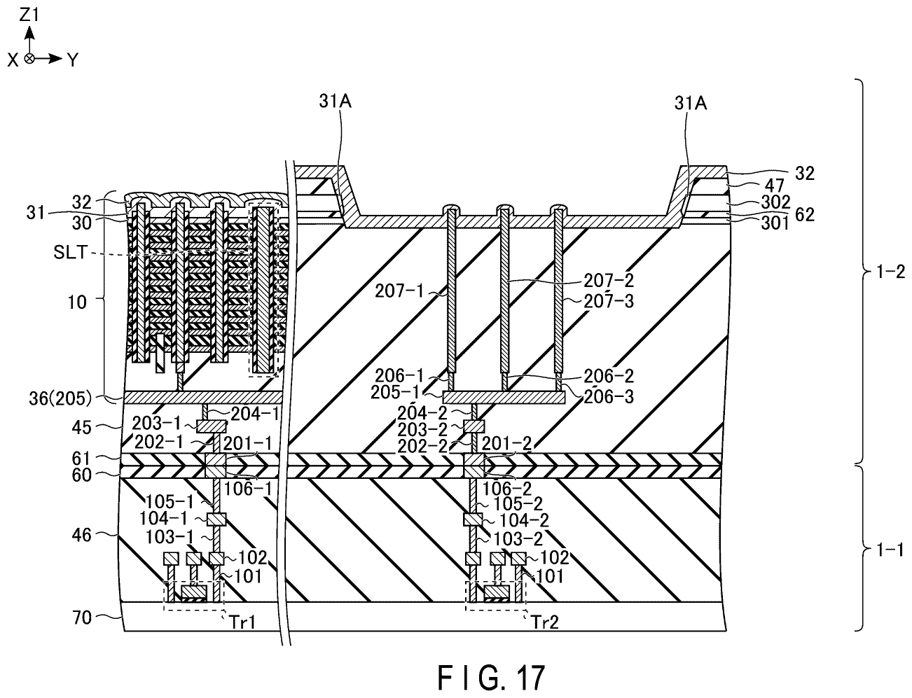

Subsequently, as shown in FIG. 17, the conductor layer 32 is stacked on the first surface of the conductor layer 31, the conductor layer 31A, the first surface of the insulator layer 47, the surface-exposed portion of the first surface of the insulator layer 45, and the one-side portions of the multiple conductor layers 207 that project from the insulator layer 45.

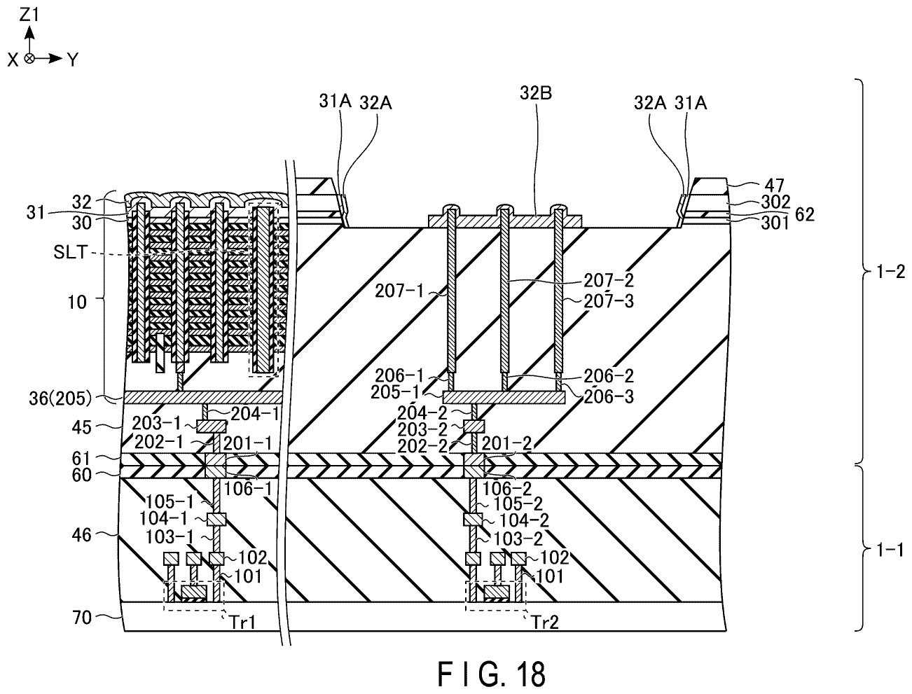

Also, as shown in FIG. 18, portions of the thus-formed conductor layer 32 other than regions that correspond to the memory cell array 10 and the conductor layer 32B are removed. The conductor layer 32 in the memory cell array 10, and the conductor layer 32B are thus formed. Also, as a result of the above process, the conductor layer 32A, which is a trace of the conductor layer 32, is formed on the wall surfaces constituted by the semiconductor layers 301 and 302 and the insulator layers 47 and 62 as shown in FIG. 18. Note that, also in this process, the one-side portion of the insulator layer 45 in the location corresponding to the region R1 may be removed as in the aforementioned process of removing the conductor layer 31 and the semiconductor layer 301 in the location corresponding to the region R1.

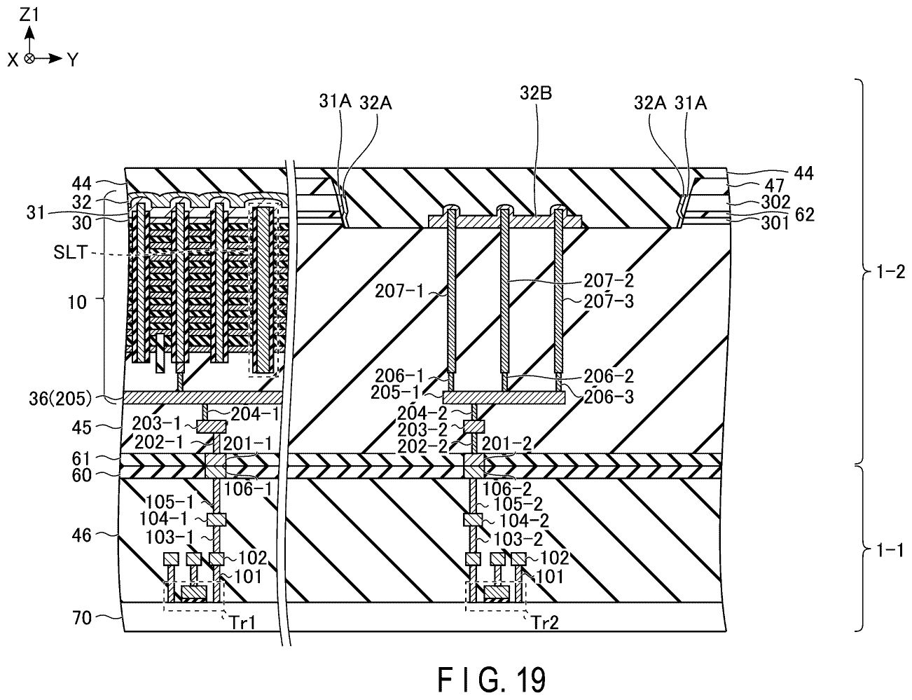

Subsequently, as shown in FIG. 19, the insulator layer 44 is formed on the first surface of the conductor layer 32, the first surface of the conductor layer 32B, the first surface of the insulator layer 47, the surface-exposed portion of the first surface of the insulator layer 45 in the location corresponding to the region R1, and the conductor layers 31A and 32A. The one-side portion of the insulator layer 44 is removed by CMP.

Next, trenches corresponding to the multiple coupling portions V1 and V2 are formed. More specifically, anisotropic etching is conducted using a mask that includes openings corresponding to the multiple coupling portions V1 and V2 so that portions where the multiple coupling portions V1 and V2 will be formed are removed at the same time. This forms the trenches. In one example, this anisotropic etching is continued until the conductor layer 32B is exposed at each of the locations overlapping the openings corresponding to the respective coupling portions V2 in the Z direction. The anisotropic etching in this process is, for example, reactive ion etching (RIE). The mask is then removed.

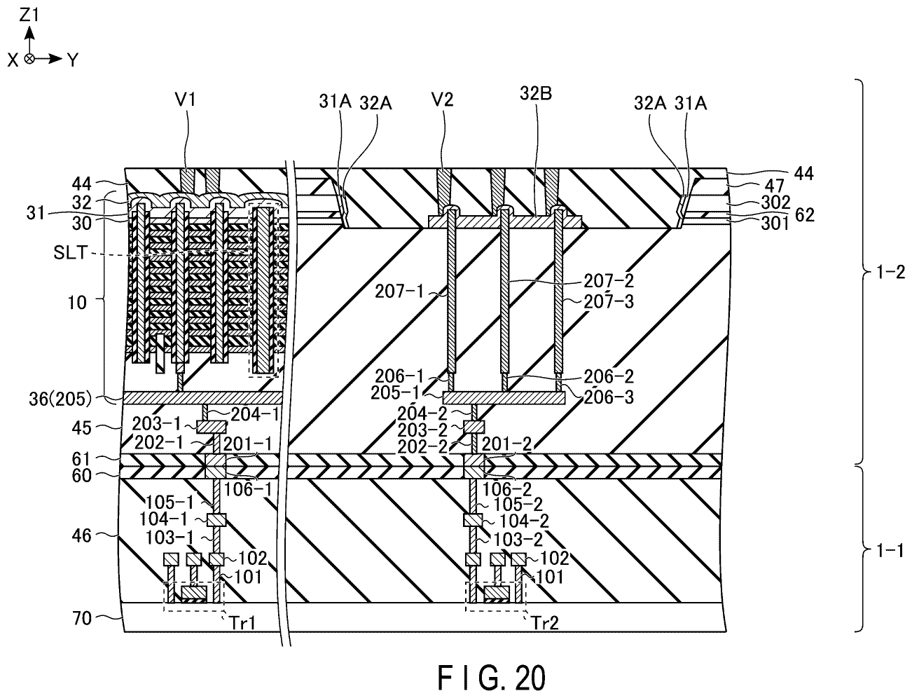

Subsequently, as shown in FIG. 20, each of the trenches corresponding to the multiple coupling portions V1 and the trenches corresponding to the multiple coupling portions V2 is filled with a conductive material. The multiple coupling portions V1 and V2 are thus formed.

Then, the conductor layer 39 is formed on the first surface of the insulator layer 44 and the first surfaces of the multiple coupling portions V1 and V2. Further, the insulator layers 48a, 48b, and 48c are formed over the first surface of the thus-formed structure except for a portion of the conductor layer 39 that corresponds to the electrode pad PD.

The semiconductor memory device 1 is formed through the manufacturing process as described above.

Note that the above described manufacturing process is only an example, and it is possible to adopt modifications such as insertion of other processes between the process steps and changes in the order of the steps. For example, the process of forming the circuit chip 1-1 as illustrated in FIG. 11 and the process of forming the structure corresponding to the memory chip 1-2 as illustrated in FIG. 12 may be concurrently performed, as the circuit chip 1-1 and the structure corresponding to the memory chip 1-2 are formed using the respective, mutually different semiconductor substrates 70 and 71.

### 1.3 Effects

According to the first embodiment, the degree of freedom in designing a semiconductor memory device 1 can be increased and enhanced. Effects of the first embodiments will be explained.

In the first embodiment, the semiconductor memory device 1 includes a circuit chip 1-1 including a semiconductor substrate 70 defining an array region AR and a peripheral region PR, and a memory chip 1-2 contacting the circuit chip 1-1 in the Z direction and electrically connected to the circuit chip 1-1 via multiple connection pads provided at a boundary region with the circuit chip 1-1. The memory chip 1-2 includes a memory cell array 10, multiple conductor layers 207, and conductor layers 32B and 39. The memory cell array 10 is arranged in the array region AR and includes a source line SL, multiple word lines WL mutually separated in the Z direction below the source line SL, and a memory pillar MP extending in the Z direction, crossing the multiple word lines WL, and including an upper end coupled to the source line SL. Each of the multiple conductor layers 207 is arranged in the peripheral region PR, extends in the Z direction, and is electrically connected to one of the multiple connection pads. The multiple conductor layers 207 each function as a contact. The conductor layer 32B contacts the upper ends of the multiple conductor layers 207. The conductor layer 39 is provided above the conductor layer 32B and electrically connected to the conductor layer 32B. The conductor layer 39 functions as an interconnect layer above the conductor layer 32B. According to such a configuration, the conductor layer 39 and the multiple conductor layers 207 are coupled together via the conductor layer 32B. Thus, easy coupling between the conductor layer 39 and the multiple conductor layers 207 is enabled and an increased degree of freedom in designing the semiconductor memory device 1 can be realized.

More specifically, a first comparative example will be supposed, in which multiple contacts electrically connected to a connection pad for connection between a circuit chip and a memory chip are directly connected to an interconnect layer arranged above the contacts via coupling portions corresponding to the respective contacts. Such a first comparative example requires alignment of positions between the multiple contacts and the multiple coupling portions in order to avoid an occurrence of poor connections between the multiple contacts and the multiple coupling portions. Also, for this position alignment, the first comparative example requires the interval between the multiple contacts and the interval between the multiple coupling portions to be equivalent.

According to the first embodiment, the conductor layer 39 and the multiple conductor layers 207 are coupled together via a pattern of the conductor layer 32B provided in a plate shape extending over the X-Y plane. This can avoid the occurrence of poor connections at the time of coupling the multiple conductor layers 207 and the conductor layer 39 together, without conducting position alignment between the multiple conductor layers 207 and the multiple coupling portions V2. Also, this enables the interval between the multiple conductor layers 207 and the interval between the multiple coupling portions V2 to be set independently from each other. The degree of freedom in designing the semiconductor memory device 1 can therefore be increased.

Accordingly, the first embodiment can also omit the step for position alignment and reduce the number of processing steps as compared to the first comparative example.

Further, according to the first embodiment, it is possible to prevent an occurrence of damage (fractures, breakage, and cracks) to the contacts.

More specifically, and for example, a second comparative example will be supposed, in which an interconnect layer to be coupled with a contact has a staircase structure in the Y-Z cross-section. In such a second comparative example, the contact is coupled with a portion of the staircase interconnect layer that is of a plate shape parallel to the semiconductor substrate. Here, this plate shape portion directly coupled with the contact will function as an electrode pad if an arrangement where the electrode pad overlaps the contact in top view is adopted in order to reduce the size of the semiconductor memory device. This could, however, incur damage (fractures, breakage, and cracks) to the contact. For example, during evaluation, a pressure applied by a probe needle may cause damage to the contact arranged directly below the electrode pad.

With the first embodiment, the occurrence of damage to the contacts can be prevented even if the electrode pad PD and the multiple conductor layers 207 are arranged to overlap each other, since the conductor layer 39 and the multiple conductor layers 207 are coupled together via the coupling portions V2 and the conductor layer 32B.

Moreover, according to the first embodiment, the electrode pad PD is provided at a position overlapping the region R1 in the Z direction. That is, the semiconductor layers 301 and 302 have been removed from the region that overlaps the electrode pad PD in the Z direction. This suppresses the interference between the electrode pad PD and the conductor layer provided on the other side from the electrode pad PD and having a different potential than the electrode pad PD. Therefore, the interface speed can be prevented from slowing down.

### 2 Modifications of First Embodiment

The foregoing first embodiment may be modified in various ways. Semiconductor memory devices according to some of the modifications of the first embodiment will be described.

### 2.1 First Modification of First Embodiment

The first embodiment has assumed a configuration in which the multiple coupling portions V1 and V2 are different members from the conductor layer 39, but this is not a limitation. The multiple coupling portions V1 and V2 may be portions of the conductor layer 39. The description will basically concentrate on the particulars of a configuration and a manufacturing method of a semiconductor memory device 1 according to a first modification of the first embodiment, which constitute differences from the configuration and the manufacturing method of the semiconductor memory device 1 according to the first embodiment.

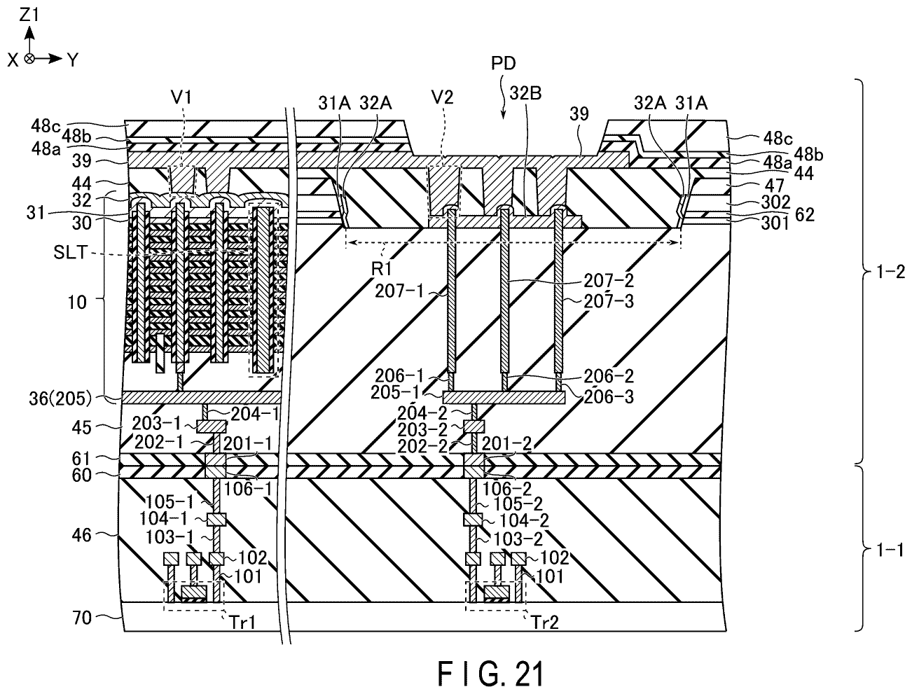

A configuration of the semiconductor memory device 1 according to the first modification of the first embodiment will be described with reference to FIG. 21. FIG. 21 is a sectional view showing an exemplary sectional structure of a circuit region CR in the semiconductor memory device 1 according to the first modification of the first embodiment.

As shown in FIG. 21, in the semiconductor memory device 1 according to the first modification of the first embodiment, the conductor layer 39 coupled with the conductor layer 32 includes an extension extending in the Y direction and multiple coupling portions V1 for coupling between this extension and the conductor layer 32. In other words, the multiple coupling portions V1 are included in the conductor layer 39 in the first modification of the first embodiment.

Also, the conductor layer 39 coupled with the conductor layer 32B includes an extension extending in the Y direction and multiple coupling portions V2 for coupling between this extension and the conductor layer 32B. In other words, the multiple coupling portions V2 are included in the conductor layer 39 in the first modification of the first embodiment.

While not shown in the figure, assuming that the height of each coupling portion V1 is H1 and the width of each coupling portion V1 in the Y direction is W1, the aspect ratio between the height H1 and the width W1, H1/W1, is, in one example, approximately 1.5 or less. Assuming that the width of each coupling portion V1 in the X direction is W2 (not shown in the figure), the aspect ratio between the height H1 and the width W2, H1/W2, is, in one example, also approximately 1.5 or less. Also, assuming that the height of each coupling portion V2 is H2 and the width of each coupling portion V2 in the Y direction is W3, the aspect ratio between the height H2 and the width W3, H2/W3, is, in one example, approximately 1.5 or less. Assuming that the width of each coupling portion V2 in the X direction is W4 (not shown in the figure), the aspect ratio between the height H2 and the width W4, H2/W4, is, in one example, also approximately 1.5 or less. With the coupling portions V1 and V2 intended to have such a configuration, the process of manufacturing the semiconductor memory device 1 can obviate the occurrence of an event where trenches corresponding to the coupling portions V1 and V2 have been insufficiently filled with a conductor in the course of forming the conductor layer 39.

Next, a method for manufacturing the semiconductor memory device 1 according to the first modification of the first embodiment will be described for the points that constitute a difference from the manufacturing method of the semiconductor memory device 1 according to the first embodiment.

In the first modification of the first embodiment, the trenches corresponding to the multiple coupling portions V1 and V2 are formed, and subsequently, the trenches are filled with a conductor so as to form the conductor layer 39.

Such a first modification of the first embodiment also produces effects equivalent to those of the first embodiment.

Moreover, according to the first modification of the first embodiment where the multiple coupling portions V1 and V2 and the extensions can be formed in the same step, it is possible to prevent the manufacturing costs from being increased.

### 2.2 Second Modification of First Embodiment

The foregoing first embodiment and first modification of the first embodiment have assumed a configuration in which the electrode pad PD overlaps the multiple coupling portions V2, the multiple conductor layers 207, and the conductor layer 32B in the Z direction, but this is not a limitation. The description will basically concentrate on the particulars of a configuration of a semiconductor memory device 1 according to a second modification of the first embodiment, which constitute differences from the configuration of the semiconductor memory device 1 according to the first modification of the first embodiment. Note that the method for manufacturing the semiconductor memory device 1 according to the second modification of the first embodiment may be similar to the method for manufacturing the semiconductor memory device 1 according to the first modification of the first embodiment.

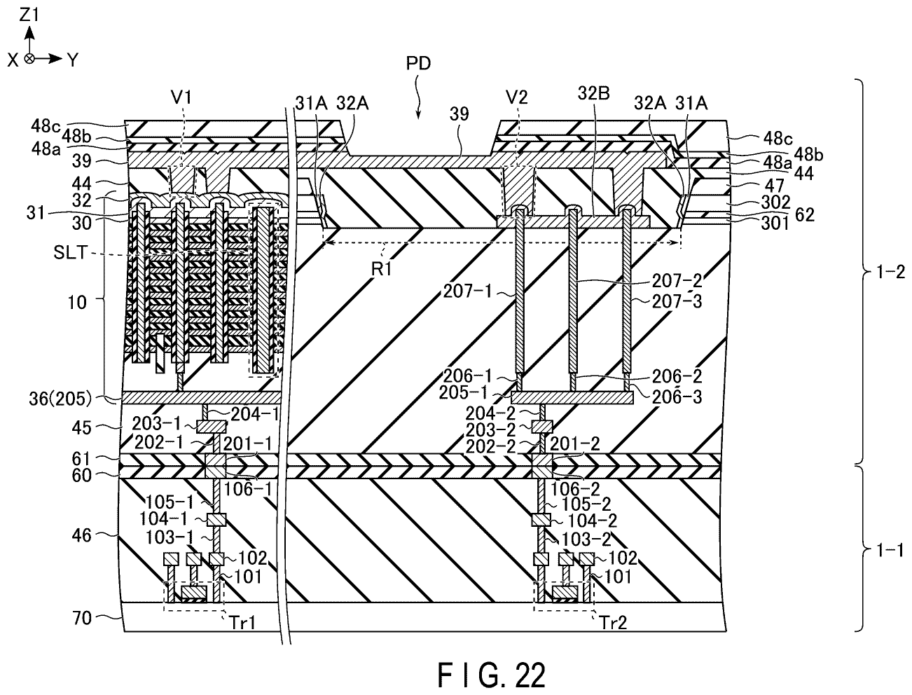

A configuration of the semiconductor memory device 1 according to the second modification of the first embodiment will be described with reference to FIG. 22. FIG. 22 is a sectional view showing an exemplary sectional structure of a circuit region CR in the semiconductor memory device 1 according to the second modification of the first embodiment.

As shown in FIG. 22, a portion of the conductor layer 39 that functions as the electrode pad PD is arranged at a position away from, for example, the multiple coupling portions V2, the multiple conductor layers 207, and the conductor layer 32B in the Z direction perspective. Due to this configuration, in the region overlapping the electrode pad PD in the Z direction, the insulator layer 44 is provided at the same layer level as the conductor layer 30, the semiconductor layers 301 and 302, and the insulator layer 62. Also in such a configuration, the electrode pad PD and the conductor layer provided on the other side from the electrode pad PD and having a different potential than the electrode pad PD are kept non-proximal to each other.

Similar to the first embodiment, the second modification of the first embodiment can also increase the degree of freedom in designing a semiconductor memory device, reduce the number of processing steps, and prevent the occurrence of damage to the contacts. Also, similar to the first modification, the second modification can prevent an increase in the manufacturing costs.

Note that, while the second modification of the first embodiment has assumed an example in which the multiple coupling portions V1 and V2 constitute portions of the conductor layer 39 as in the first modification of the first embodiment, the second modification is not limited to such a configuration. The second modification may adopt, as in the first embodiment, a configuration where the multiple coupling portions V1 and V2 are different members from the conductor layer 39. Note also that, unlike in the first embodiment and the first modification of the first embodiment, the multiple coupling portions V2 in the second modification of the first embodiment are not arranged to correspond to the multiple conductor layers 207, respectively. That is, the multiple coupling portions V2 serve the purpose as long as they have an electrical connection with the conductor layer 32B, and they are not required to correspond to the respective conductor layers 207.

### 2.3 Third Modification of First Embodiment

The first embodiment, the first modification of the first embodiment, and the second modification of the first embodiment have assumed a configuration in which the interconnect layer above the multiple coupling portions V1 and V2 is constituted by one conductor layer, but this is not a limitation. The interconnect layer above the multiple coupling portions V1 and V2 may be constituted by multiple conductor layers. The description will basically concentrate on the particulars of a configuration and a manufacturing method of a semiconductor memory device 1 according to a third modification of the first embodiment, which constitute differences from the configuration and the manufacturing method of the semiconductor memory device 1 according to the first modification of the first embodiment.

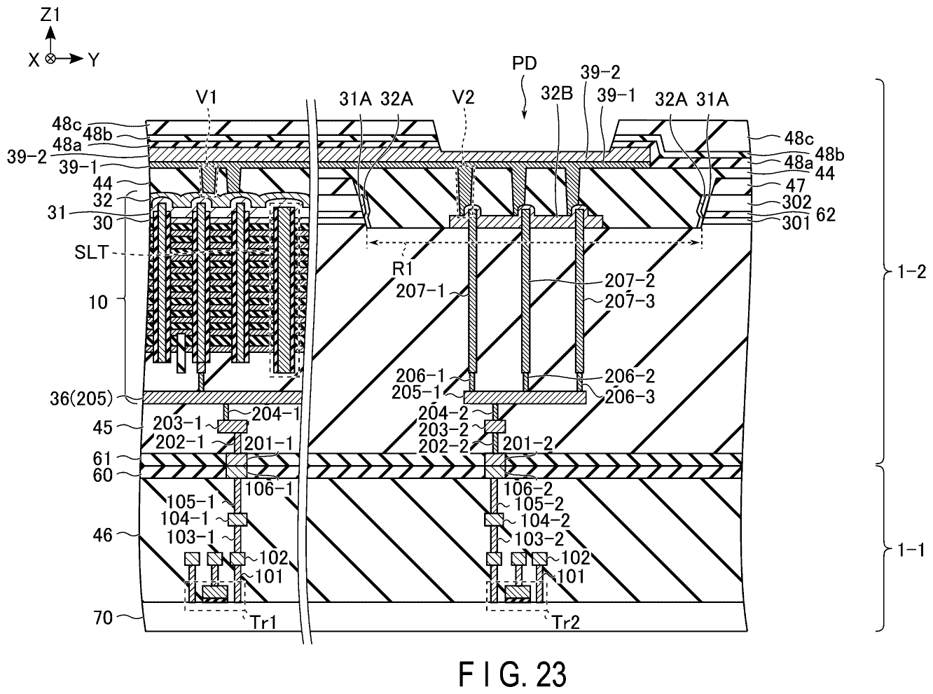

A configuration of the semiconductor memory device 1 according to the third modification of the first embodiment will be described with reference to FIG. 23. FIG. 23 is a sectional view showing an exemplary sectional structure of a circuit region CR in the semiconductor memory device 1 according to the third modification of the first embodiment.

As shown in FIG. 23, the conductor layer 39 in the semiconductor memory device 1 according to the third modification of the first embodiment is constituted by conductor layers 39-1 and 39-2.

The conductor layer 39-1 includes a portion contacting the conductor layer 32 and a portion contacting the conductor layer 32B. The portion of the conductor layer 39-1 that contacts the conductor layer 32 includes an extension extending in the Y direction and multiple coupling portions V1 for coupling between this extension and the conductor layer 32. The multiple coupling portions V1 may each be regarded as a via that fills a space assumed between the extension and the conductor layer 32. Also, the portion of the conductor layer 39-1 that contacts the conductor layer 32B includes an extension extending in the Y direction and multiple coupling portions V2 for coupling between this extension and the conductor layer 32B. The multiple coupling portions V2 may each be regarded as a via that fills a space assumed between the extension and the conductor layer 32B. The conductor layer 39-1 contains, for example, tungsten.

The conductor layer 39-2 is provided on the first surface of the portion of the conductor layer 39-1 that includes the multiple coupling portions V1 and the first surface of the portion of the conductor layer 39-1 that includes the multiple coupling portions V2. The conductor layer 39-2 contains, for example, aluminum.

Note that each of the aspect ratios H1/W1, H1/W2, H2/W3, and H2/W4 of the coupling portions V1 and V2 in the third modification of the first embodiment is not limited to approximately 1.5 or less, the exemplary range noted for the first modification of the first embodiment. The aspect ratios H1/W1, H1/W2, H2/W3, and H2/W4 may each be greater than 1.5.

The method for manufacturing the semiconductor memory device 1 according to the third modification of the first embodiment may be similar to the method for manufacturing the semiconductor memory device 1 according to the first modification of the first embodiment, except that the conductor layer 39-1 is formed in such a manner as to fill the trenches as in the formation of the conductor layer 39 in the first modification of the first embodiment and then the conductor layer 39-2 is formed. Here, after the formation of the conductor layer 39-1 and before the formation of the conductor layer 39-2, the first surface of the conductor layer 39-1 is not subjected to, for example, a CMP process.

The third modification of the first embodiment also produces effects equivalent to those of the first embodiment.

Moreover, the third modification of the first embodiment can realize an enhanced crack resistance of the interconnect layer. More specifically, as described above, the interconnect layer provided on the one side from the conductor layer 32B is constituted by multiple conductor layers including the conductor layers 39-1 and 39-2. Such a configuration can prevent the interconnect layer from being cracked in response to an event such as a probe contacting the electrode pad PD provided at the interconnect layer, or a wire being bonded to the electrode pad PD.

### 2.4 Fourth Modification of First Embodiment

The first embodiment, the first modification of the first embodiment, the second modification of the first embodiment, and the third modification of the first embodiment have assumed a configuration in which the first surface of the insulator layer 44 has a uniform height, but this is not a limitation. The first surface of the insulator layer 44 may have a level difference. The description will basically concentrate on the particulars of a configuration and a manufacturing method of a semiconductor memory device 1 according to a fourth modification of the first embodiment, which constitute differences from the configuration and the manufacturing method of the semiconductor memory device 1 according to the first modification of the first embodiment.

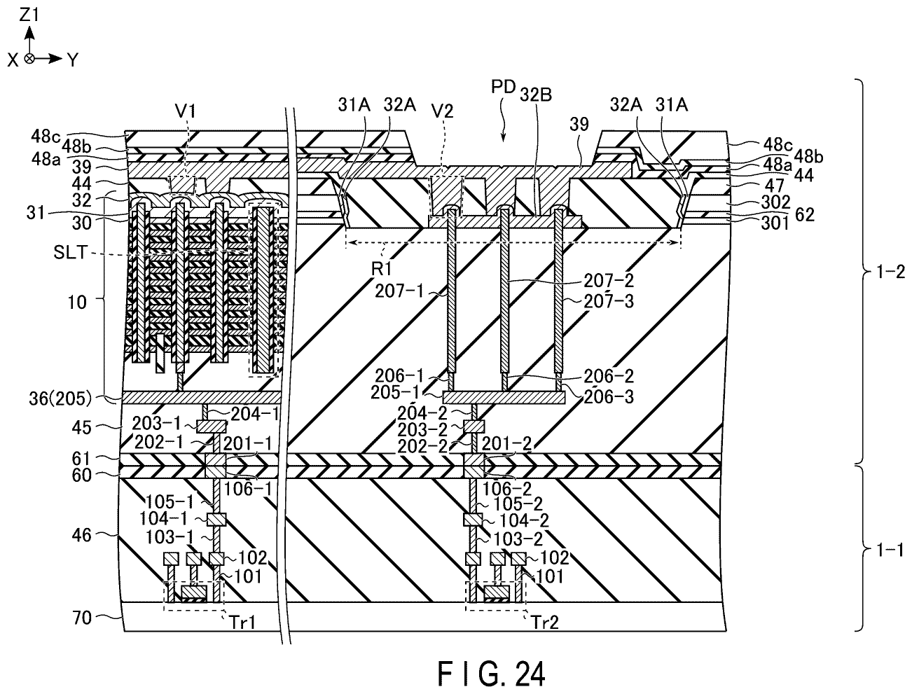

A configuration of the semiconductor memory device 1 according to the fourth modification of the first embodiment will be described with reference to FIG. 24. FIG. 24 is a sectional view showing an exemplary sectional structure of a circuit region CR in the semiconductor memory device 1 according to the fourth modification of the first embodiment.

In the fourth modification of the first embodiment, the first surface of the insulator layer 44 located in the region R1 is on the other side from the first surface of the insulator layer 44 located on the first surface of the insulator layer 47. The first surface of the insulator layer 44 located in the region R1 is, in one example, at substantially the same level as the first surface of the insulator layer 44 located on the first surface of the conductor layer 32. While not shown in FIG. 24, in one example, the first surface of the insulator layer 44 also has a level difference near the boundary between the region where the conductor layer 32 is provided and its neighboring region.

The method for manufacturing the semiconductor memory device 1 according to the fourth modification of the first embodiment may be similar to the method for manufacturing the semiconductor memory device 1 according to the first modification of the first embodiment, except that CMP to remove the insulator layer 44 is omitted or terminated before the first surface of the insulator layer 44 becomes flat in the processing step corresponding to FIG. 19 referred to for the first embodiment.

The fourth modification of the first embodiment also produces effects equivalent to those of the first modification of the first embodiment.

### 2.5 Fifth Modification of First Embodiment

The first embodiment, the first modification of the first embodiment, the second modification of the first embodiment, the third modification of the first embodiment, and the fourth modification of the first embodiment have assumed a configuration in which the multiple coupling portions V2 are arranged in a grid pattern, but this is not a limitation. The description will basically concentrate on the particulars of a configuration of a semiconductor memory device 1 according to a fifth modification of the first embodiment, which constitute differences from the configuration of the semiconductor memory device 1 according to the first embodiment. Note that the method for manufacturing the semiconductor memory device 1 according to the fifth modification of the first embodiment may be substantially similar to the method for manufacturing the semiconductor memory device 1 according to the first embodiment.

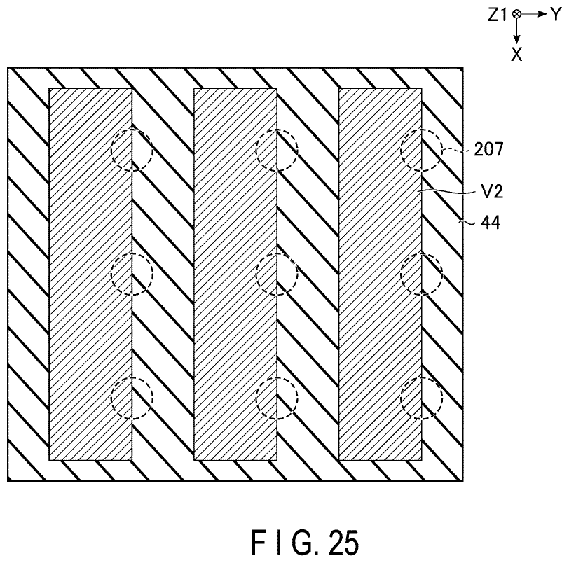

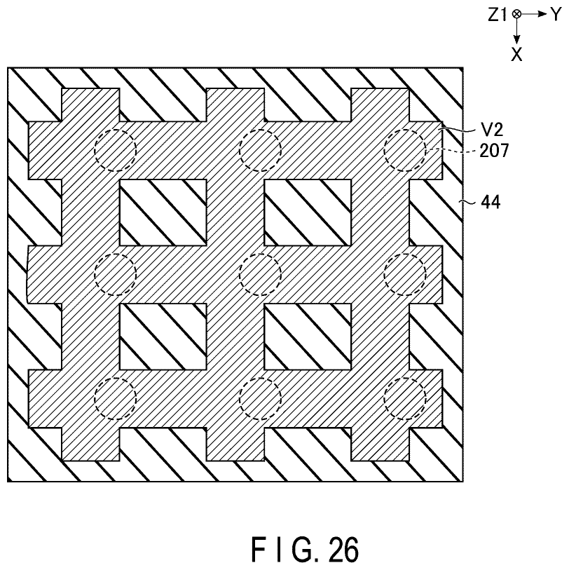

A configuration of the semiconductor memory device 1 according to the fifth modification of the first embodiment will be described with reference to FIGS. 25 and 26. Each of FIGS. 25 and 26 is a sectional view showing an exemplary sectional structure of a circuit region CR in the semiconductor memory device 1 according to the fifth modification of the first embodiment. FIGS. 25 and 26 show a region corresponding to FIG. 9 referred to for the first embodiment.

As shown in FIG. 25, the multiple coupling portions V2 in the X-Y cross-section are each provided so as to extend in the X direction. In other words, the multiple coupling portions V2 are provided as multiple line structures arranged in the Y direction. In the X-Y cross section, the multiple coupling portions V2 may be displaced in the Y direction from the multiple conductor layers 207.

Also, as shown in FIG. 26, the semiconductor memory device 1 may adopt a configuration in which the conductor layers 32B and 39 are coupled together via one coupling portion V2. In this case, such a coupling portion V2 has, for example, a mesh structure constituted by multiple portions extending in the X direction and multiple portions extending in the Y direction in the X-Y cross-section.

The fifth modification of the first embodiment also produces effects equivalent to those of the first embodiment.

### 3 Second Embodiment

Next, a semiconductor memory device 1 according to a second embodiment will be described.

### 3.1 Configurations

Configurations for the semiconductor memory device 1 according to the second embodiment will be described. The description will basically concentrate on the particulars of a configuration of the semiconductor memory device 1 according to the second embodiment, which constitute differences from the configuration of the semiconductor memory device 1 according to the first embodiment.

### 3.1.1 Interconnect Layers of Semiconductor Memory Device

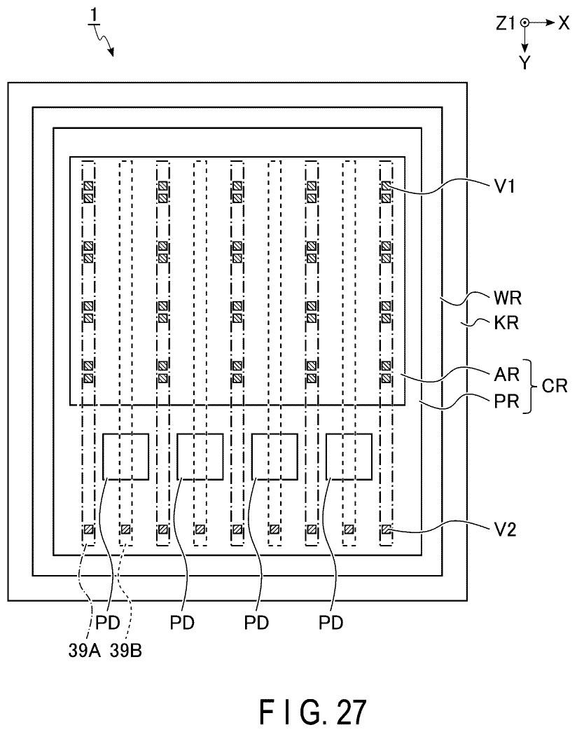

FIG. 27 will be referred to for describing an example of the interconnect layers provided in the semiconductor memory device 1 according to the second embodiment. FIG. 27 is a plan view showing an exemplary planar layout of the semiconductor memory device 1 according to the second embodiment.

The semiconductor memory device 1 according to the second embodiment includes conductor layers 39A and 39B with multiple of each provided. The multiple conductor layers 39A and 39B correspond to the conductor layer 39 in the first embodiment.

The multiple conductor layers 39A and 39B are provided so as to each extend in the Y direction. In one example, the multiple conductor layers 39A and 39B are alternately arranged in the X direction.

Each of the multiple conductor layers 39A in one example includes, similar to the conductor layers 39 in the first and second modifications of the first embodiment, multiple coupling portions V1. Accordingly, each of the multiple conductor layers 39A is coupled to the source line SL via the multiple coupling portions V1.

Also, each of the multiple conductor layers 39A and 39B in one example includes, similar to the conductor layers 39 in the first and second modifications of the first embodiment, multiple coupling portions V2. Accordingly, each of the multiple conductor layers 39A and 39B is coupled to the peripheral circuit PERI via the multiple coupling portions V2.

As will be described, the multiple conductor layers 39B each include a region forming the electrode pad PD.

### 3.1.2 Overall Sectional Structure of Semiconductor Memory Device

For the overall sectional structure of the semiconductor memory device 1, a description will be given of each of the sectional structures of a part including the conductor layer 39A and a part including the conductor layer 39B.

3.1.2.1 Sectional Structure of Part of Semiconductor Memory Device that Includes Conductor Layer 39A

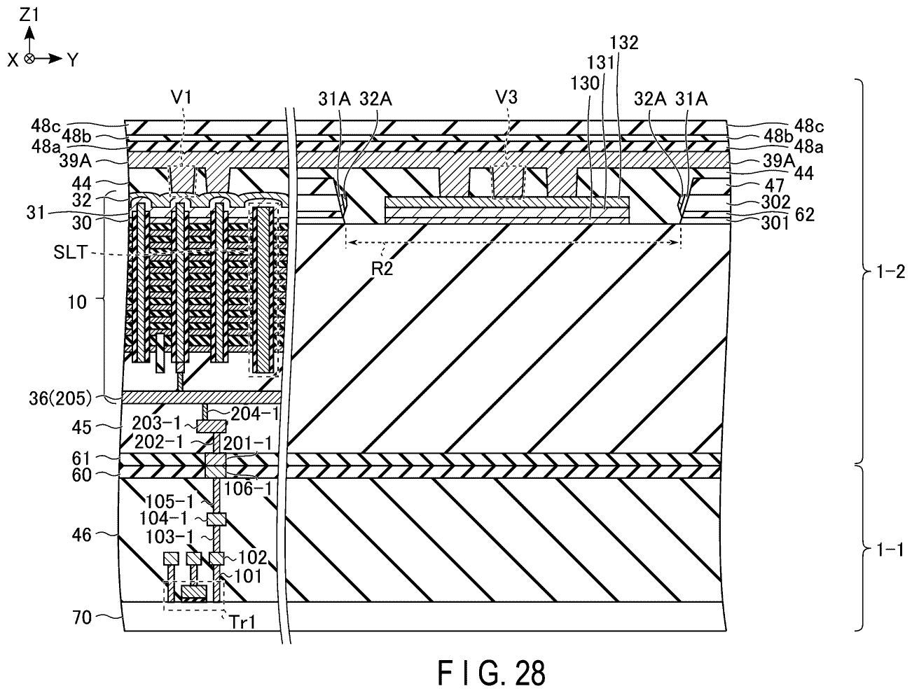

FIG. 28 will be referred to for describing a sectional structure of the part of the semiconductor memory device 1 that includes the conductor layer 39A. FIG. 28 is a sectional view showing an exemplary sectional structure of a circuit region CR in the semiconductor memory device 1 according to the second embodiment. What is shown in FIG. 28 is a sectional structure of the part of the semiconductor memory device 1 that includes the conductor layer 39A.

The sectional structure of the circuit chip 1-1 shown in FIG. 28 is similar to that of the circuit chip 1-1 in the first embodiment except that it does not include the transistor Tr2 or the conductor layers 101 to 106 for coupling with the transistor Tr2.

The memory chip 1-2 includes, in one example, conductor layers 36 (205), 39A, 130, 131, 132, 201-1, 202-1, 203-1, and 204-1, insulator layers 44, 45, 47, 48a, 48b, 48c, 61, and 62, semiconductor layers 301 and 302, and a memory cell array 10. The conductor layers 201-1, 202-1, 203-1, and 204-1, and the insulator layer 61 have the same configurations as those in the first embodiment.

The insulator layer 45 has the same configuration as that in the first embodiment except for the level of its first surface. In one example, in the cross-section shown in FIG. 28, the first surface of the insulator layer 45 in the region other than the region of the memory cell array 10 is at the same level as the second surface of the conductor layer 30 in the memory cell array 10.

In the region other than the region of the memory cell array 10, in one example, the conductor layers 130, 131, and 132 are stacked in this order on a portion of the first surface of the insulator layer 45. The conductor layers 130, 131, and 132 are formed of respective conductive materials. The conductive material forming the conductor layer 130 is the same as the conductive material forming the conductor layer 30. The conductive material forming the conductor layer 131 is the same as the conductive material forming the conductor layer 31. The conductive material forming the conductor layer 132 is the same as the conductive material forming the conductor layer 32. The conductor layer 130 is included in the same layer level as the conductor layer 30, which is on the other side from the conductor layer 31. As will be described later, the conductor layers 131 and 132 are formed in, for example, the same step as the step for forming the conductor layers 31 and 32. In the following description, a region of the first surface of the insulator layer 45 that encompasses the portion where the conductor layers 130, 131, and 132 are provided and its surrounding portion will be called a “region R2”. In this region R2, the conductor layer 30 and the insulator layers 47 and 62 are absent.

The semiconductor layer 301 is provided on portions that are other than the region of the memory cell array 10 and that are next to the region R2. The semiconductor layer 301 and the conductor layers 30 and 130 are at the same layer level as one another. The insulator layer 62 is provided on the first surface of the semiconductor layer 301. The semiconductor layer 302 is provided on the first surface of the insulator layer 62. The semiconductor layers 301 and 302 are electrically insulated from the source line SL, as in the first embodiment. The insulator layer 47 is provided on the first surface of the semiconductor layer 302. Due to the above configuration, the region R2 shown in FIG. 28 is sandwiched in the Y direction by two wall surfaces each constituted by the semiconductor layers 301 and 302 and the insulator layers 47 and 62.

The insulator layer 44 is provided on a portion of the first surface of the insulator layer 45 that is in the region R2 and other than the portion where the conductor layers 130, 131, and 132 are provided, on the first surface of the insulator layer 47, and also on portions of the first surfaces of the conductor layers 32 and 132 that are other than the portions where the later described multiple coupling portions V1 and V3 are provided. In one example, the first surface of the insulator layer 44 has a uniform height. Note that, as in the fourth modification of the first embodiment, the first surface of the insulator layer 44 may have a level difference near the boundary between the region R2 and the region next to the region R2.

On the two wall surfaces sandwiching the region R2 in the Y direction and constituted by the semiconductor layers 301 and 302 and the insulator layers 47 and 62, conductor layers 31A and 32A resulting from the later described formation of the conductor layers 31, 32, 131, and 132 may be provided. Similar to the case of the region R1 in the first embodiment, the semiconductor memory device 1 in one example includes, outside the part shown in FIG. 28, two wall surfaces sandwiching the region R2 in the X direction and constituted by the semiconductor layers 301 and 302 and the insulator layers 47 and 62. Thus, the region R2 in one example is surrounded by four wall surfaces in top view. These two wall surfaces may also be provided with the conductor layers 31A and 32A resulting from the later described formation of the conductor layers 31, 32, 131, and 132. With the above configuration, the conductor layers 31A and 32A may be provided between each of the wall surfaces and the insulator layer 44. The conductor layers 31A and 32A may be provided partially or entirely over each wall surface.

The conductor layer 39A is provided on the first surface of the insulator layer 44, the portions of the first surface of the conductor layer 32 where the insulator layer 44 is not provided, and the portions of the first surface of the conductor layer 132 where the insulator layer 44 is not provided. The conductor layer 39A includes the multiple coupling portions V1 and V3, and an extension which extends in the Y direction. The extension electrically connects the multiple coupling portions V1 and V3 together. The multiple coupling portions V1 may each be regarded as a via that fills a space assumed between the extension and a portion of the first surface of the conductor layer 32. The multiple coupling portions V3 may each be regarded as a via that fills a space assumed between the extension and a portion of the first surface of the conductor layer 132.

With the above configuration, the conductor layer 32 and the conductor layers 130, 131, and 132 are coupled together. The conductor layers 130, 131, and 132 thus function as a backing interconnect. Also, the conductor layers 130, 131, and 132 function as an extended source line SL.

Note that, as shown in FIG. 27, the conductor layer 39A in one example is coupled to the peripheral circuit PERI in the circuit chip 1-1 through elements or components similar to the conductor layers 201 to 207. With this configuration, the conductor layer 32 and the peripheral circuit PERI can be coupled to each other via the conductor layers 39A, 101 to 106, and 201 to 207, and the multiple coupling portions V1.

While not shown in the figure, assuming that the height of each coupling portion V3 is H3 and the width of each coupling portion V3 in the Y direction is W5, the aspect ratio between the height H3 and the width W5, H3/W5, is, in one example, approximately 1.5 or less. Assuming that the width of each coupling portion V3 in the X direction is W6 (not shown in the figure), the aspect ratio between the height H3 and the width W6, H3/W6, is, in one example, also approximately 1.5 or less. With the coupling portions V3 intended to have such a configuration, the process of manufacturing the semiconductor memory device 1 can obviate the occurrence of an event where trenches corresponding to the coupling portions V3 have been insufficiently filled with a conductor in the course of forming the conductor layer 39A.

3.1.2.2 Sectional Structure of Part of Semiconductor Memory Device that Includes Conductor Layer 39B

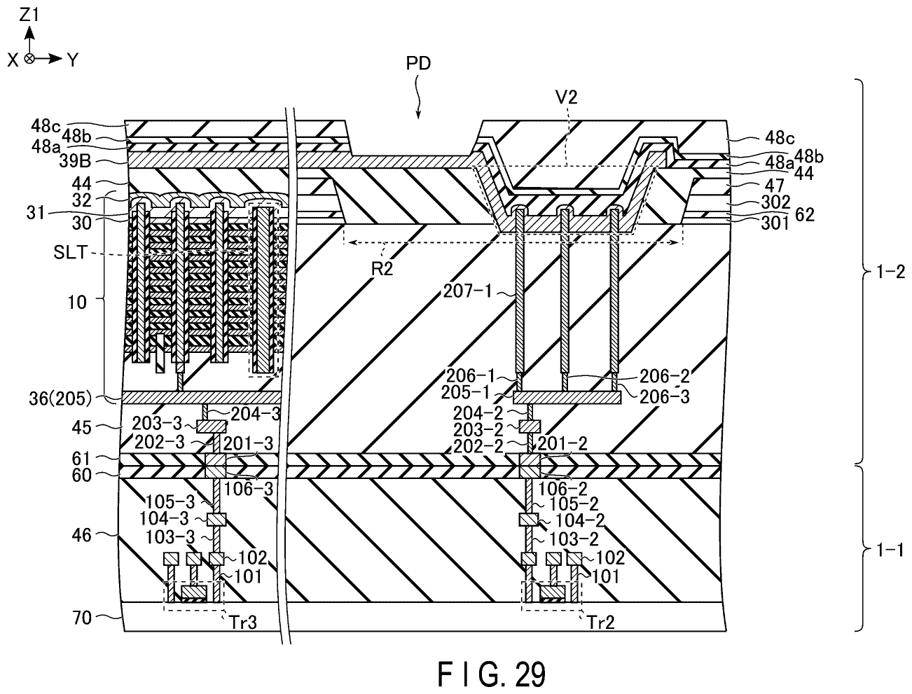

FIG. 29 will be referred to for describing a sectional structure of the part of the semiconductor memory device 1 that includes the conductor layer 39B. FIG. 29 is a sectional view showing an exemplary sectional structure of the circuit region CR in the semiconductor memory device 1 according to the second embodiment. What is shown in FIG. 29 is a sectional structure of the part of the semiconductor memory device 1 that includes the conductor layer 39B.

The sectional structure of the circuit chip 1-1 shown in FIG. 29 is similar to that of the circuit chip 1-1 in the first embodiment except that it includes, in place of the transistor Tr1 and the conductor layers 101-1 to 106-1, their respective comparable configurations, namely, a transistor Tr3 and conductor layers 101-3, 102-3, 103-3, 104-3, 105-3, and 106-3 for coupling with the transistor Tr3. Also, the sectional structure of the memory chip 1-2 in the array region AR is similar to that of the memory chip 1-2 in the first embodiment except that it includes, in place of the conductor layers 201-1, 202-1, 203-1, and 204-1 in the region of the memory cell array 10, their respective comparable configurations, namely, conductor layers 201-3, 202-3, 203-3, and 204-3 in the region of the memory cell array 10.

The description will basically concentrate on the particulars of a configuration of the memory chip 1-2 in the cross-section shown in FIG. 29, which constitute differences from the configuration in the cross-section shown in FIG. 28. In the cross-section shown in FIG. 29, the semiconductor memory device 1 includes the conductor layer 39B.

In the region other than the region of the memory cell array 10, the region R2 includes, similar to the region R1 in the first embodiment, a portion where the multiple conductor layers 207 are provided. The respective one-side portions of the multiple conductor layers 207 project from the first surface of the insulator layer 45. In one example, in the region other than the region of the memory cell array 10, portions of the first surface of the insulator layer 45 that surrounds the respective conductor layers 207 in the region R2 are located on the other side from the other portions of the first surface of the insulator layer 45.

In the region other than the region of the memory cell array 10, two walls constituted by the semiconductor layers 301 and 302 and the insulator layers 47 and 62 and sandwiching the region R2 in the Y direction are provided as in the cross-section shown in FIG. 28. Note that, while not shown in FIG. 29, the conductor layers 31A and 32A resulting from the formation of the conductor layers 31, 32, 131, and 132 may also be present on such two wall surfaces constituted by the semiconductor layers 301 and 302 and the insulator layers 47 and 62 in the cross-section including the conductor layer 39B.

The insulator layer 44 is provided on the first surface of the insulator layer 45 in the region R2 and also on the first surface of the insulator layer 47, except for the portions of the first surface of the insulator layer 45 that respectively surround the multiple conductor layers 207 in the region R2. The insulator layer 44 is not provided on the one-side portions of the multiple conductor layers 207, either.

The conductor layer 39B is provided on portions of the first surface of the insulator layer 44, the portions of the first surface of the insulator layer 45 that respectively surround the multiple conductor layers 207 in the region R2, and the one-side portions of the multiple conductor layers 207. The conductor layer 39B is formed so as to cover the one-side portions of the multiple conductor layers 207. The conductor layer 39B has a level difference at the location where it is coupled with the multiple conductor layers 207 from the portion provided on the first surface of the insulator layer 44. The conductor layer 39B at this location is provided on the other side from the portion provided on the first surface of the insulator layer 44 and functions as a coupling portion V2 electrically connecting with the multiple conductor layers 207.

The conductor layer 39B includes a region exposed at the first surface of the semiconductor memory device 1. In one example, this region forms the electrode pad PD for coupling with a device external to the semiconductor memory device 1. The electrode pad PD is provided at a position overlapping the region R2 in the Z direction. As such, the semiconductor layers 301 and 302 are not present in the region overlapping the electrode pad PD in the Z direction. Also, in the Z direction perspective, the electrode pad PD is provided away from the multiple conductor layers 207. In one example, the electrode pad PD is provided at a higher level than the first surface of the insulator layer 44. That is, in the region overlapping the electrode pad PD in the Z direction, the insulator layer 44 is provided at the same layer level as the semiconductor layers 301 and 302 and the insulator layer 62.

With the above configuration, for example, the electrode pad PD and the transistor Tr2 can be coupled to each other via the conductor layers 101 to 106 and 201 to 207. In other words, the electrode pad PD and the peripheral circuit PERI are electrically connected to each other.

Note that, while not shown in the figures, the portion shown in FIG. 29 that includes the multiple conductor layers 207 and the portion shown in FIG. 28 that includes the conductor layers 130, 131, and 132 may be, in one example, separated from each other in the X direction by a wall constituted by the semiconductor layers 301 and 302 and the insulator layers 47 and 62. That is, for example, the portion including the multiple conductor layers 207 and the portion where the conductor layers 130, 131, and 132 are provided are not required to be arranged in the same region R2 but may be disposed in mutually different regions enclosed by respective walls constituted by the semiconductor layers 301 and 302 and the insulator layers 47 and 62.

### 3.2 Method for Manufacturing Semiconductor Memory Device

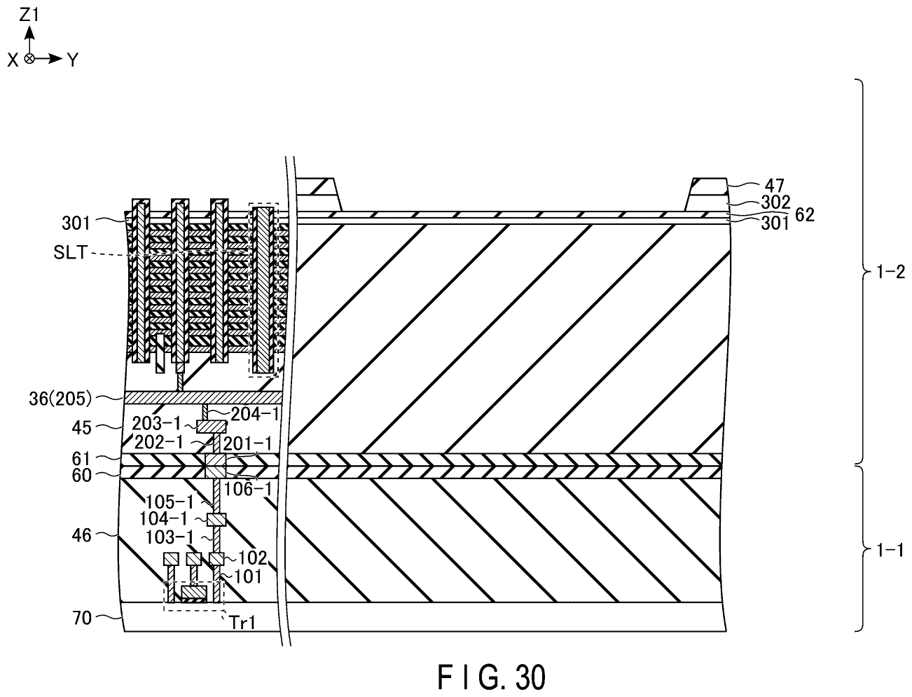

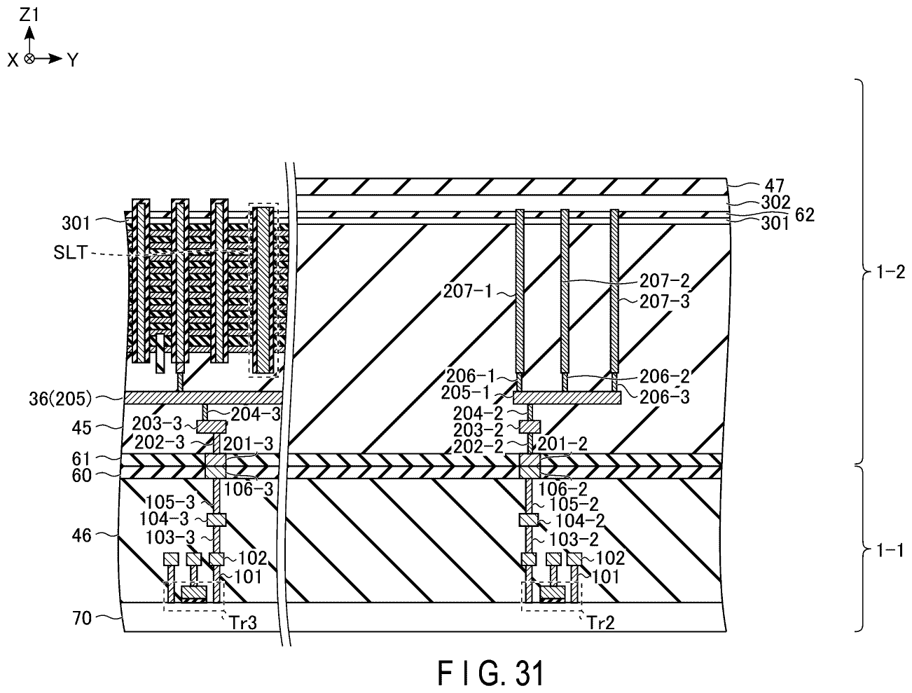

A method for manufacturing the semiconductor memory device 1 will be described with reference to FIGS. 30 to 37. FIGS. 30 to 37 are sectional views for explaining an exemplary method for manufacturing the semiconductor memory device 1 according to the second embodiment. The sectional views shown in FIGS. 30, 32, 34, and 36 each cover a part corresponding to FIG. 28. The sectional views shown in FIGS. 31, 33, 35, and 37 each cover a part corresponding to FIG. 29.

First, steps similar to those explained with reference to FIGS. 11 to 13 for the first embodiment are performed.

Also, as shown in FIGS. 30 and 31, the insulator layer 47 and the semiconductor layer 302 in the location corresponding to the memory cell array 10 are removed. Together with this removal, the insulator layer 47 and the semiconductor layer 302 in the location corresponding to the region R2 are removed in the part corresponding to FIG. 28, as shown in FIG. 30.

Subsequently, in the location corresponding to the memory cell array 10, a portion of each stacked film 52 that is located on the one side from the insulator layer 62 is removed so that the semiconductor film 51 located on the one side from the insulator layer 62 is exposed at the surface. The insulator layer 62 in the location corresponding to the memory cell array 10, and also in the location corresponding to the region R2 in the part corresponding to FIG. 28, is removed. This exposes the semiconductor layer 301, the respective one-side portions of the multiple memory pillars MP, and the respective one-side portions of the multiple members SLT at the surface in the location corresponding to the memory cell array 10 and also in the location corresponding to the region R2 in the part corresponding to FIG. 28.

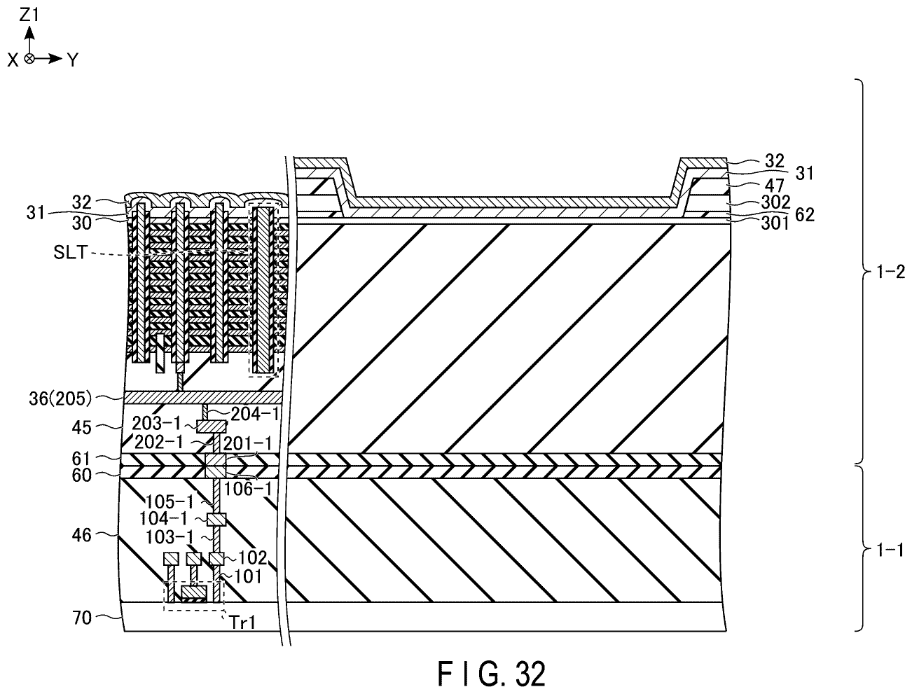

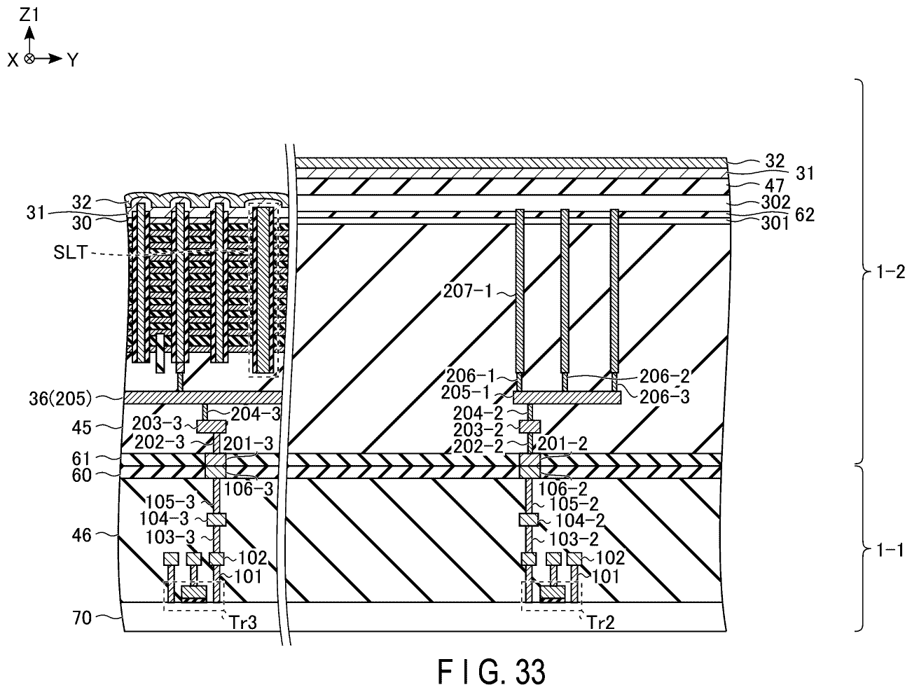

Then, in both the part corresponding to FIG. 28 and the part corresponding to FIG. 29, the conductor layers 31 and 32 are stacked in this order on the surface-exposed portions of the first surface of the semiconductor layer 301, the surface-exposed portions of the memory pillars MP, the one-side portions of the multiple members SLT, and the first surface of the insulator layer 47 as shown in FIGS. 32 and 33. Here, portions of the semiconductor layer 301 that respectively correspond to the conductor layers 30 and 130 are turned into conductor portions by diffusion of impurity.

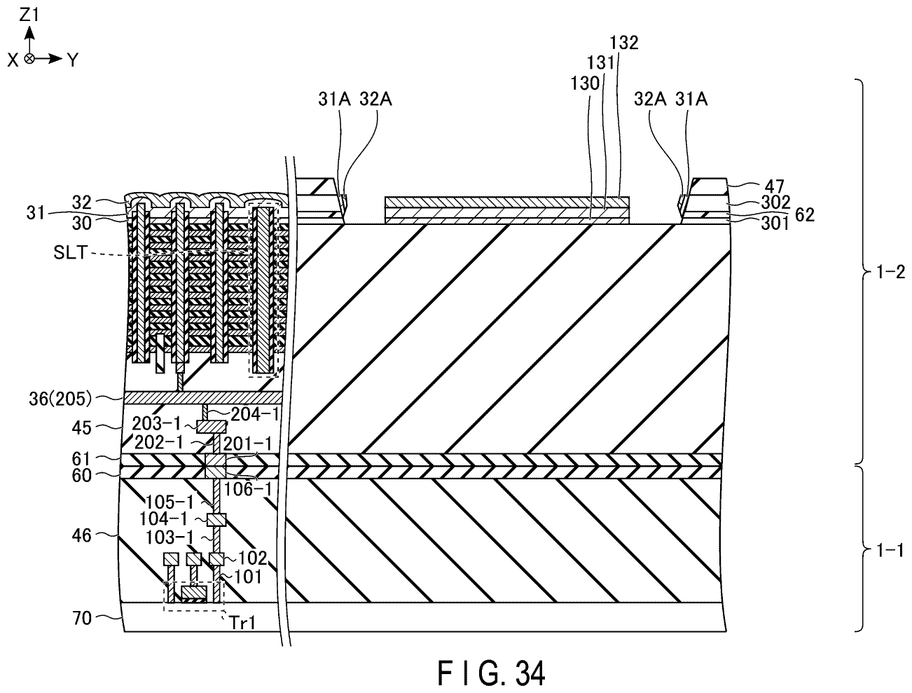

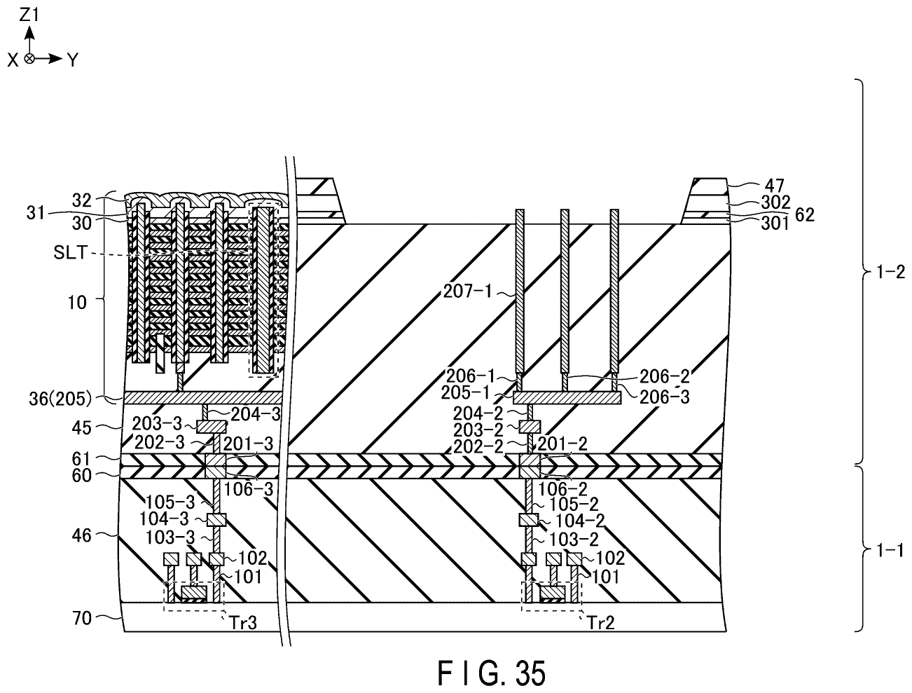

Then, etching or the like is conducted with a mask so that the semiconductor layer 301, which includes the conductor portions corresponding to the conductor layers 30 and 130, and also the conductor layers 31 and 32 are removed except for the portions corresponding to the conductor layers 130, 131, and 132 and the source line SL constituted by the conductor layers 30, 31, and 32, as shown in FIGS. 34 and 35. The conductor layers 30, 130, 131, and 132 are therefore formed by the above steps. Together, portions of the first surface of the insulator layer 45 are exposed at the surface in the location corresponding to the region R2. In the part corresponding to FIG. 29, the respective one-side portions of the multiple conductor layers 207 are also exposed at the surface in the location corresponding to the region R2, as shown in FIG. 35. Also, as a result of the above process, in the part corresponding to FIG. 28, the conductor layers 31A and 32A, which are traces of the conductor layers 31, 32, 131, and 132, are formed on the wall surfaces constituted by the semiconductor layers 301 and 302 and the insulator layers 47 and 62, as shown in FIG. 34.

Then, the insulator layer 44 is formed on the first surface of the conductor layer 32, the first surface of the conductor layer 132, the first surface of the insulator layer 47, the surface-exposed portion of the first surface of the insulator layer 45 in the location corresponding to the region R2, and the conductor layers 31A and 32A. The one-side portion of the insulator layer 44 is removed by CMP.

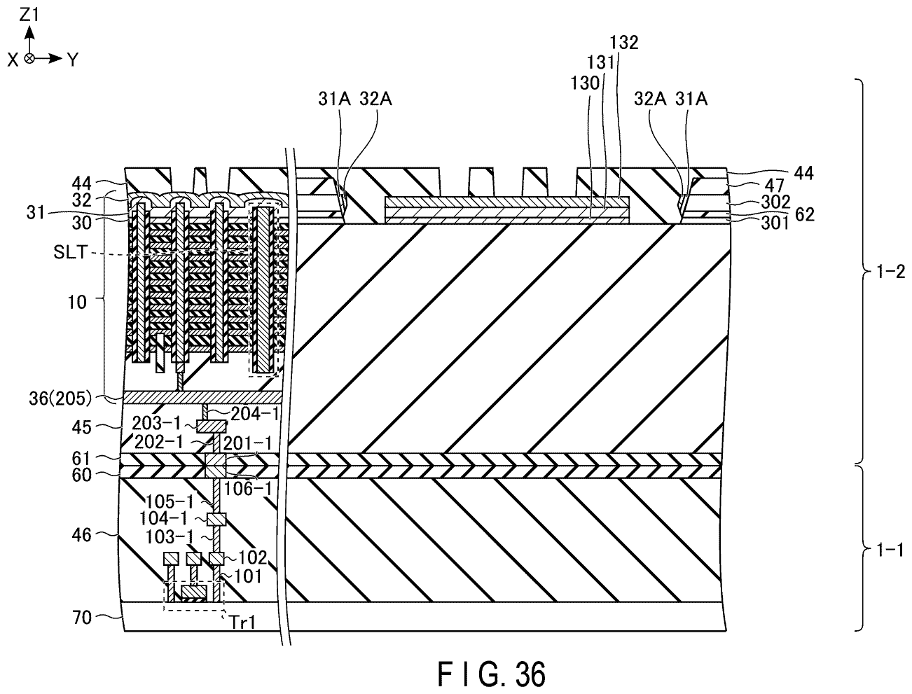

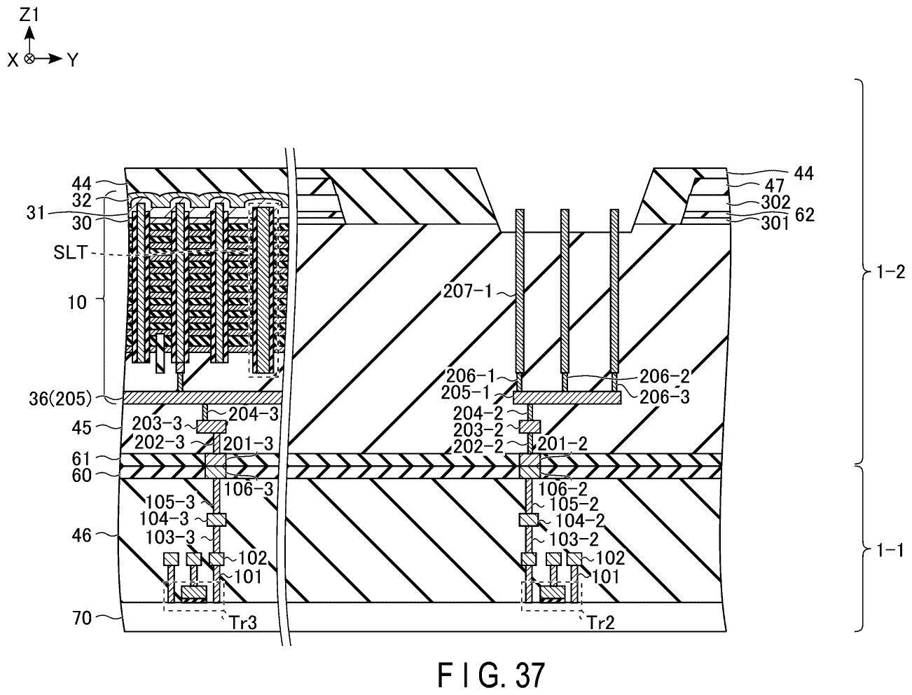

Subsequently, in the part corresponding to FIG. 28, trenches corresponding to the multiple coupling portions V1 and V3 are formed as shown in FIG. 36. This formation of the trenches is conducted in a similar manner to the formation of the trenches corresponding to the multiple coupling portions V1 and V2 in the first embodiment. Also, in the part corresponding to FIG. 29, the insulator layer 44 and a one-side portion of the insulator layer 45 that are in the location surrounding the multiple conductor layers 207 in the region R2 are removed as shown in FIG. 37.

Also, the conductor layer 39A is formed up to the level which is further on the one side from the insulator layer 44, while filling the trenches corresponding to the multiple coupling portions V1 and V3. Also, the conductor layer 39B is formed on the insulator layer 44 and the portion of the first surface of the insulator layer 45 so as to be in contact with the multiple conductor layers 207. Further, the insulator layers 48a, 48b, and 48c are formed over the first surface of the thus-formed structure except for a portion of the conductor layer 39B that corresponds to the electrode pad PD.

The semiconductor memory device 1 is therefore formed through the manufacturing process as described above.

### 3.3 Effects

The degree of freedom in designing a semiconductor memory device can also be increased and enhanced by the second embodiment. Effects of the second embodiments will be explained.

In the second embodiment, the semiconductor memory device 1 includes a circuit chip 1-1 including a semiconductor substrate 70 defining an array region AR and a peripheral region PR, and a memory chip 1-2 contacting the circuit chip 1-1 in the Z direction and electrically connected to the circuit chip 1-1 via multiple connection pads provided at a boundary region with the circuit chip 1-1. The memory chip 1-2 includes a memory cell array 10, conductor layers 39A, 130 to 132, and 207, and a semiconductor layer 301. The memory cell array 10 is arranged in the array region AR and includes a source line SL, multiple word lines WL mutually separated in the Z direction below the source line SL, and a memory pillar MP extending in the Z direction, crossing the multiple word lines WL, and including an upper end coupled to the source line SL. Each of the multiple conductor layers 207 is arranged in the peripheral region PR, extends in the Z direction, and is electrically connected to one of the multiple connection pads. The conductor layers 130 to 132 are provided in the peripheral region PR, included in the same layer level as the source line SL, and separated from the source line SL. The conductor layers 130 to 132 are arranged at a position not overlapping the multiple conductor layers 207 in the Z direction. The conductor layers 39A and 39B include a portion electrically connected to the conductor layers 130 to 132 and a portion electrically connected to one of the multiple conductor layers 207. This portion of the conductor layer 39A functions as an interconnect layer provided on the one side from the conductor layers 130 to 132. The semiconductor layer 301 in the peripheral region PR is included in the same layer level as the source line SL. Also, the semiconductor layer 301 has a structure in which a portion overlapping the multiple conductor layers 207 and the conductor layers 130 to 132 in the Z direction has been removed. In the configuration as described above, the conductor layers 130 to 132 function as a backing interconnect for the conductor layer 39A. Accordingly, complexity of the interconnects can be avoided, and the degree of freedom in designing the semiconductor memory device 1 can be increased.

More specifically, a third comparative example will be supposed, which involves, as a dead space, a space that includes conductor layers with polysilicon or the like intended for forming a source line and left in the peripheral region and that does not function as a part of the circuit in a semiconductor memory device. In such a third comparative example, additional layers are provided at the same layer level as the interconnect layers in order to, for example, reduce the resistance in the interconnects or enhance electro-migration (EM) resistance characteristics. This could, however, incur complexity in the interconnects.

According to the second embodiment, the conductor layers 130 to 132 originally intended for forming the source line SL and provided in the peripheral region PR function as a backing interconnect for the conductor layer 39A. In this manner, the conductor layers 130 to 132 resulting from the conductor layers provided for forming the source line SL are utilized as an interconnect, so that the space that would otherwise become a dead space as in the third comparative example can be effectively used. Accordingly, the second embodiment can avoid complexity of the interconnects in instances of reducing the resistance in the interconnects or enhancing EM resistance characteristics. The degree of freedom in designing the semiconductor memory device 1 can therefore be increased.

Moreover, by utilizing the conductor layers 130 to 132 provided in a region corresponding to the dead space in the third comparative example as a backing interconnect as described above, the semiconductor memory device 1 can be prevented from being upsized.

### 4 Modifications of Second Embodiment

The foregoing second embodiment may be modified in various ways. Semiconductor memory devices according to some of the modifications of the second embodiment will be described.

### 4.1 First Modification of Second Embodiment

The second embodiment has assumed a configuration in which the conductor layers 130, 131, and 132 function as a backing interconnect for the conductor layer 39A, but this is not a limitation. The conductor layers 130, 131, and 132 may, in addition to functioning as a backing interconnect, function as an interconnect for coupling two different conductor layers 39A together. The description will basically concentrate on the particulars of a configuration of a semiconductor memory device 1 according to a first modification of the second embodiment, which constitute differences from the configuration of the semiconductor memory device 1 according to the second embodiment. Note that the method for manufacturing the semiconductor memory device 1 according to the first modification of the second embodiment may be substantially similar to the method for manufacturing the semiconductor memory device 1 according to the second embodiment.

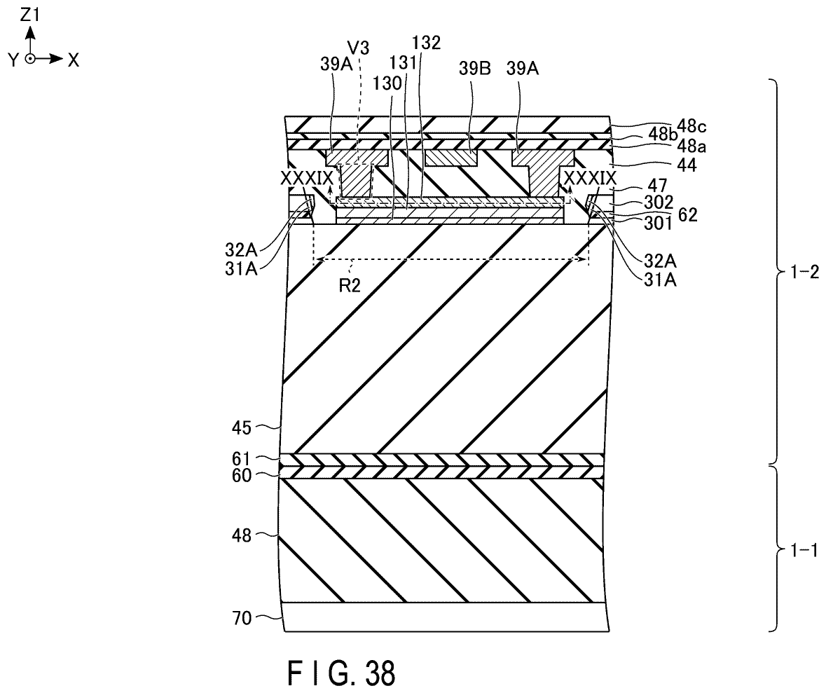

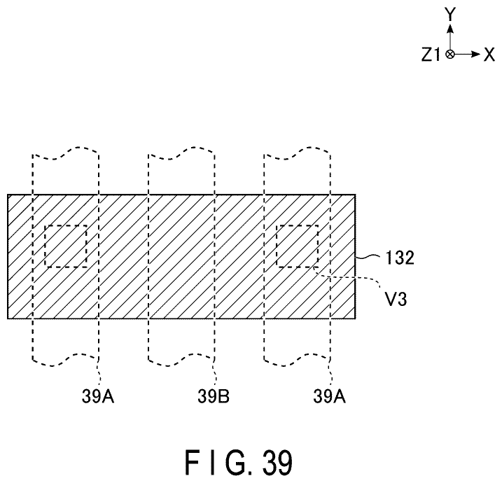

A configuration of the semiconductor memory device 1 according to the first modification of the second embodiment will be described with reference to FIGS. 38 and 39. FIG. 38 is a sectional view showing an exemplary sectional structure of a circuit region CR in the semiconductor memory device 1 according to the first modification of the second embodiment. FIG. 39 is a sectional view taken along the line XXXIX-XXXIX indicated in FIG. 38 and shows exemplary connections of interconnect layers in the semiconductor memory device 1 according to the first modification of the second embodiment.

What is shown in FIG. 38 is a sectional structure covering the region R2. FIG. 38 illustrates an example where the region R2 encompasses, in the X-Z cross-section, two conductor layers (two sub-interconnect portions) 39A, and one conductor layer 39B.

As shown in FIGS. 38 and 39, the conductor layers 130, 131, and 132 in the first modification of the second embodiment extend in the X direction so as to couple the two conductor layers 39A arranged in the X direction. These two conductor layers 39A are each coupled to the conductor layers 130, 131, and 132 via their own coupling portions V3.

With such a configuration, the conductor layers 130, 131, and 132 function as a backing interconnect for coupling the two conductor layers 39A to each other in a bypassing manner on the other side from the conductor layers 39A.

Note that, while the bypass backing interconnect for coupling the two conductor layers 39A has been described, the first modification of the second embodiment is not limited to this configuration. The conductor layers 130, 131, and 132 may also be provided as a backing interconnect for coupling, for example, two conductor layers 39B to each other in a bypassing manner. In this case, the two conductor layers 39B are each coupled to the conductor layers 130, 131, and 132 via a configuration similar to the coupling portion V3 of each conductor layer 39A.

The first modification of the second embodiment also produces effects equivalent to those of the second embodiment.

### 4.2 Second Modification of Second Embodiment

The foregoing second embodiment and first modification of the second embodiment have assumed a configuration in which the conductor layers 130, 131, and 132 function as a backing interconnect for the conductor layer 39A, but this is not a limitation. The conductor layers 130, 131, and 132 may be configured to function as a device element. The description will basically concentrate on the particulars of a configuration and a manufacturing method of a semiconductor memory device 1 according to a second modification of the second embodiment, which constitute differences from the configuration and the manufacturing method of the semiconductor memory device 1 according to the second embodiment.

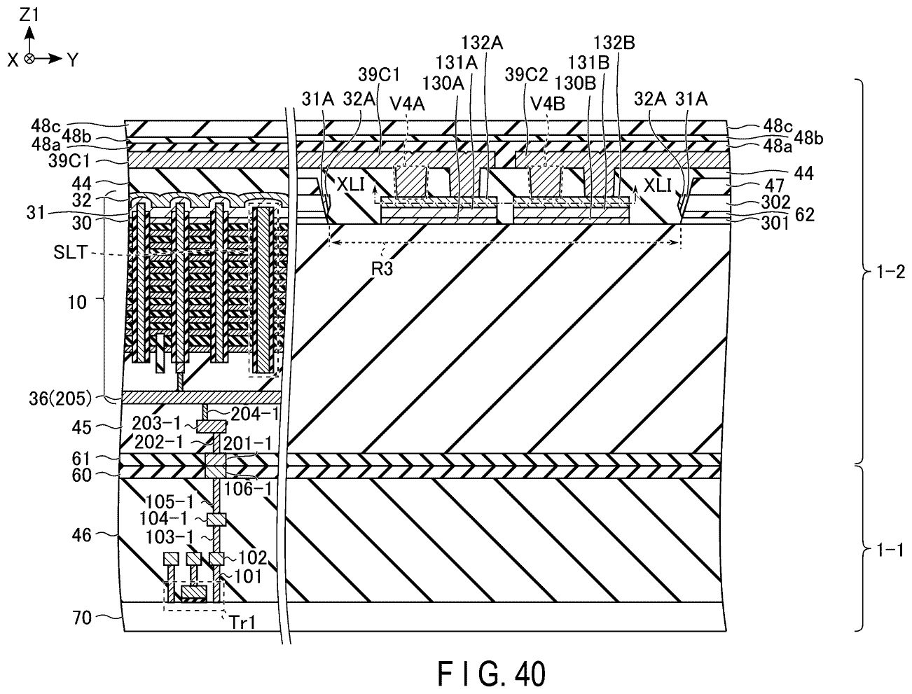

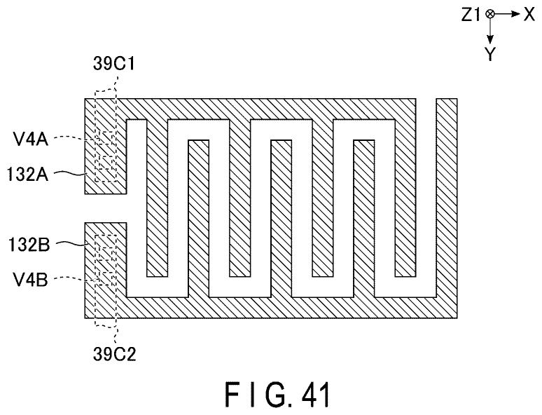

A configuration of the semiconductor memory device 1 according to the second modification of the second embodiment will be described with reference to FIGS. 40 and 41. FIG. 40 is a sectional view showing an exemplary sectional structure of a circuit region CR in the semiconductor memory device 1 according to the second modification of the second embodiment. FIG. 41 is a sectional view taken along the line XLI-XLI indicated in FIG. 40 and shows exemplary connections of interconnect layers in the semiconductor memory device 1 according to the second modification of the second embodiment.

In one example, as shown in FIG. 40, conductor layers 130A, 131A, and 132A are stacked in this order on a portion of the first surface of the insulator layer 45 in the region other than the region of the memory cell array 10. Also, in one example, in the region other than the region of the memory cell array 10, conductor layers 130B, 131B, and 132B which are electrically separated from the conductor layers 130A, 131A, and 132A are provided on a portion of the first surface of the insulator layer 45 that is away from the position of the conductor layers 130A, 131A, and 132A in the Y direction. The conductor layers 130A, 130B, 131A, 131B, 132A, and 132B are formed of respective conductive materials. The conductive materials forming the conductor layers 130A and 130B are the same as the conductive material forming the conductor layer 30. The conductive materials forming the conductor layers 131A and 131B are the same as the conductive material forming the conductor layer 31. The conductive materials forming the conductor layers 132A and 132B are the same as the conductive material forming the conductor layer 32. The conductor layers 130A and 130B are included in the same layer level as the conductor layer 30. In one example, the conductor layers 131A, 131B, 132A, and 132B are, similar to the conductor layers 131 and 132, formed in the same step as the step for forming the conductor layers 31 and 32. In the following description, a region of the first surface of the insulator layer 45 that encompasses the portion where the conductor layers 130A, 130B, 131A, 131B, 132A, and 132B are provided and its surrounding portion will be called a “region R3”. In this region R3, the semiconductor layers 301 and 302, the conductor layer 30, and the insulator layers 47 and 62 are absent.

The semiconductor memory device 1 includes conductor layers (sub-interconnect portions) 39C1 and 39C2 arranged in the Y direction and located at the same layer level as the conductor layers 39A and 39B. The conductor layers 39C1 and 39C2 are electrically separated from each other. The conductor layer 39C1 includes an extension extending in the Y direction and at least one or more coupling portions V4A. The coupling portions V4A may each be regarded as a via that fills a space assumed between the extension and the conductor layer 132A. The conductor layer 39C2 includes an extension extending in the Y direction and at least one or more coupling portions V4B. The coupling portions V4B may each be regarded as a via that fills a space assumed between the extension and the conductor layer 132B.

While not shown in the figure, assuming that the height of each of the coupling portions V4A and V4B is H4 and the width of each of the coupling portions V4A and V4B in the Y direction is W7, the aspect ratio between the height H4 and the width W7, H4/W7, is, in one example, approximately 1.5 or less. Assuming that the width of each of the coupling portions V4A and V4B in the X direction is W8 (not shown in the figure), the aspect ratio between the height H4 and the width W8, H4/W8, is, in one example, also approximately 1.5 or less. With the coupling portions V4A and V4B intended to have such a configuration, the process of manufacturing the semiconductor memory device 1 can obviate the occurrence of an event where trenches corresponding to the coupling portions V4A and V4B have been insufficiently filled with a conductor in the course of forming the conductor layers 39C1 and 39C2.

As shown in FIG. 41, the conductor layer 132A includes, in the X-Y plane, an X-direction extending portion and multiple Y-direction extending portions each connected at one Y-direction side of the X-direction extending portion. Here, the one Y-direction side refers to the conductor layer 39C2 side among the conductor layer 39C1 side and the conductor layer 39C2 side. Also, the other Y-direction side is the conductor layer 39C1 side among the conductor layer 39C1 side and the conductor layer 39C2 side. On the other hand, the conductor layer 132B includes, on the one Y-direction side from the X-direction extending portion of the conductor layer 132A, an X-direction extending portion and multiple Y-direction extending portions each connected at the other Y-direction side of its X-direction extending portion. According to such a configuration, the conductor layers 132A and 132B each have a comb-shaped pattern structure in the Z direction perspective. Also, the conductor layers 132A and 132B are provided so that the Y-direction extending portions of the conductor layer 132A and the Y-direction extending portions of the conductor layer 132B are alternately arranged in the X direction. While not shown in the figure, the conductor layers 131A and 130A also have a similar comb-shaped pattern structure to the conductor layer 132A on the second surface of the conductor layer 132A. Likewise, while not shown in the figure, the conductor layers 131B and 130B also have a similar comb-shaped pattern structure to the conductor layer 132B on the second surface of the conductor layer 132B.

Note that the conductor layers 39C1 and 39C2 may each be, for example, electrically connected to elements or components similar to the conductor layers 207 in a cross-section not shown in the figure, so as to be coupled to the peripheral circuit PERI.

With the configuration described above, the conductor layers 130A, 130B, 131A, 131B, 132A, and 132B function as a capacitor. That is, the conductor layers 130A, 130B, 131A, 131B, 132A, and 132B constitute a so-called comb capacitor.

The method for manufacturing the semiconductor memory device 1 according to the second modification of the second embodiment may be similar to the method for manufacturing the semiconductor memory device 1 according to the second embodiment, except that the conductor layers 39C1 and 39C2 are formed in a similar manner to the conductor layers 39A and 39B in the second embodiment and that the conductor layers 130A, 130B, 131A, 131B, 132A, and 132B are formed in a similar manner to the conductor layers 130, 131, and 132 in the second embodiment.

The second modification of the second embodiment also produces effects equivalent to those of the second embodiment.

### 4.3 Third Modification of Second Embodiment

The second modification of the second embodiment has assumed a configuration in which a comb capacitor is provided on the one side from the insulator layer 45, but this is not a limitation. The semiconductor memory device 1 may be provided with a device element differing from a comb capacitor on the one side from the insulator layer 45. The description will basically concentrate on the particulars of a configuration of a semiconductor memory device 1 according to a third modification of the second embodiment, which constitute differences from the configuration of the semiconductor memory device 1 according to the second modification of the second embodiment. Note that the method for manufacturing the semiconductor memory device 1 according to the third modification of the second embodiment may be substantially similar to the method for manufacturing the semiconductor memory device 1 according to the second modification of the second embodiment.

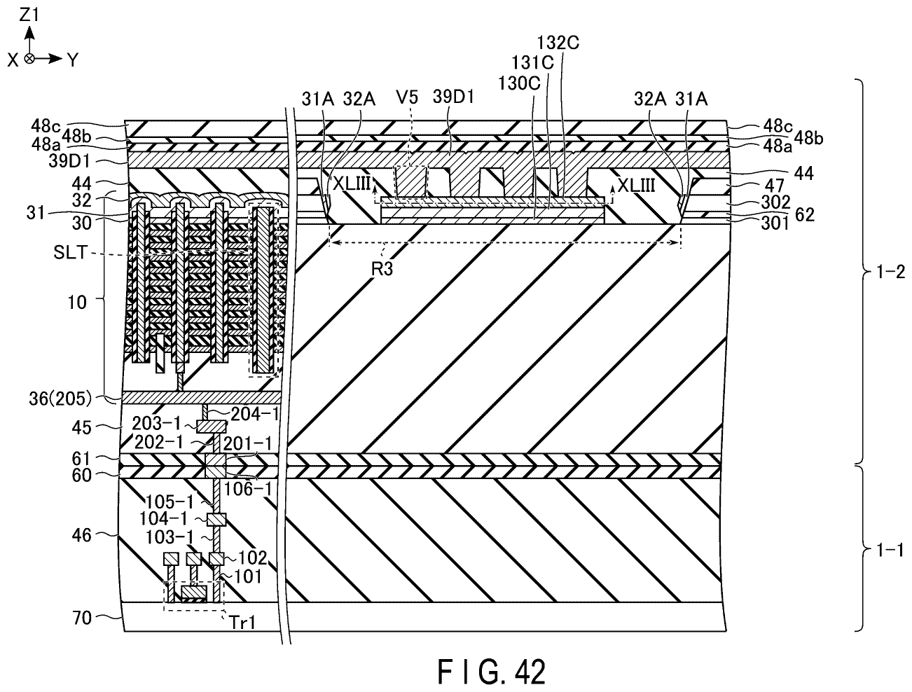

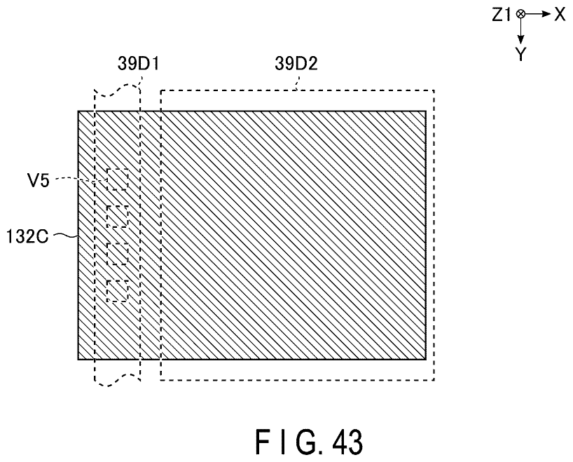

A configuration of the semiconductor memory device 1 according to the third modification of the second embodiment will be described with reference to FIGS. 42 and 43. FIG. 42 is a sectional view showing an exemplary sectional structure of a circuit region CR in the semiconductor memory device 1 according to the third modification of the second embodiment. FIG. 43 is a sectional view taken along the line XLIII-XLIII indicated in FIG. 42 and shows exemplary connections of interconnect layers in the semiconductor memory device 1 according to the third modification of the second embodiment.

In one example, as shown in FIG. 42, conductor layers 130C, 131C, and 132C are stacked in this order on a portion of the first surface of the insulator layer 45 in the region other than the region of the memory cell array 10. The conductor layers 130C, 131C, and 132C are formed of respective conductive materials. The conductive material forming the conductor layer 130C is the same as the conductive material forming the conductor layer 30. The conductive material forming the conductor layer 131C is the same as the conductive material forming the conductor layer 31. The conductive material forming the conductor layer 132C is the same as the conductive material forming the conductor layer 32. The conductor layers 130C, 131C, and 132C are each formed to have a pattern which extends over the X-Y plane in a plate shape. The conductor layer 130C is included in the same layer level as the conductor layer 30. In one example, the conductor layers 131C and 132C are, similar to the conductor layers 131 and 132, formed in the same step as the step for forming the conductor layers 31 and 32. In the third modification of the second embodiment, the region R3 refers to a region of the first surface of the insulator layer 45 that encompasses a portion where the plate pattern by the conductor layers 130C, 131C, and 132C is provided and its surrounding portion.

The semiconductor memory device 1 includes a conductor layer (sub-interconnect portion) 39D1 at the same layer level as the conductor layers 39A and 39B. The conductor layer 39D1 includes an extension extending in the Y direction above one side edge portion of the plate pattern of the conductor layer 132C, and at least one or more coupling portions V5. The coupling portions V5 may each be regarded as a via that fills a space assumed between the extension and the conductor layer 132C.

While not shown in the figure, assuming that the height of each coupling portion V5 is H5 and the width of each coupling portion V5 in the Y direction is W9, the aspect ratio between the height H5 and the width W9, H5/W9, is, in one example, approximately 1.5 or less. Assuming that the width of each coupling portion V5 in the X direction is W10 (not shown in the figure), the aspect ratio between the height H5 and the width W10, H5/W10, is, in one example, also approximately 1.5 or less. With the coupling portions V5 intended to have such a configuration, the process of manufacturing the semiconductor memory device 1 can obviate the occurrence of an event where trenches corresponding to the coupling portions V5 have been insufficiently filled with a conductor in the course of forming the conductor layer 39D1.

Also, the semiconductor memory device 1 includes a conductor layer (sub-interconnect portion) 39D2 located at the same layer level as the conductor layer 39D1 and separated from the conductor layer 39D1. As shown in FIG. 43, the conductor layer 39D2 in one example is arranged at the same layer level as, and next in the X direction to, the extension of the conductor layer 39D1. The conductor layer 39D2 is provided at a position away from the one side edge portion of the plate pattern of the conductor layer 132C above which the extension of the conductor layer 39D1 is provided, so that the conductor layer 39D2 overlaps the conductor layer 132C in the Z direction. In one example, the conductor layer 39D2 has a plate shape extending over the X-Y plane.

Note that, similar to the conductor layers 39C1 and 39C2 in the second modification of the second embodiment, the conductor layers 39D1 and 39D2 may each be, for example, electrically connected to elements or components similar to the conductor layers 207 in a cross-section not shown in the figure, so as to be coupled to the peripheral circuit PERI.

With the configuration described above, the conductor layer 132C coupled to the conductor layer 39D1, and the conductor layer 39D2 function as a plate capacitor.

The third modification of the second embodiment also produces effects equivalent to those of the second embodiment.

### 4.4 Fourth Modification of Second Embodiment

The second embodiment, the first modification of the second embodiment, the second modification of the second embodiment, and the third modification of the second embodiment have assumed a configuration in which the extension of the interconnect layer provided on the one side from the upper surface of the source line SL is coupled to the conductor layers provided on the other side from this interconnect layer through the vias (coupling portions) filled with conductors. However, no limitations are intended by this. The interconnect layer provided on the one side from the upper surface of the source line SL may be coupled to the conductor layers provided on the other side from the interconnect layer through a via that is not occluded. The description will basically concentrate on the particulars of a configuration of a semiconductor memory device 1 according to a fourth modification of the second embodiment, which constitute differences from the configuration of the semiconductor memory device 1 according to the second embodiment. Note that the method for manufacturing the semiconductor memory device 1 according to the fourth modification of the second embodiment may be substantially similar to the method for manufacturing the semiconductor memory device 1 according to the second embodiment.

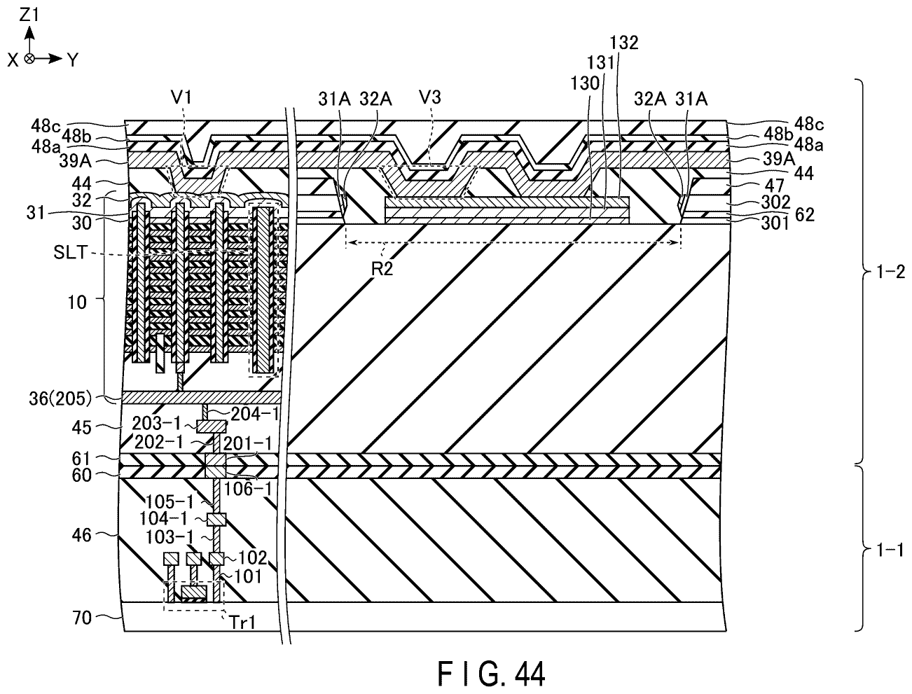

A configuration of the semiconductor memory device 1 according to the fourth modification of the second embodiment will be described with reference to FIG. 44. FIG. 44 is a sectional view showing an exemplary sectional structure of a circuit region CR in the semiconductor memory device 1 according to the fourth modification of the second embodiment.

In the fourth modification of the second embodiment, the conductor layer 39A includes a coupling portion V1 having a first surface at the level lower than the second surface of a portion (extension) of the conductor layer 39A that is other than the coupling portions V1 and V3, and a second surface in contact with the conductor layer 32. Also, the conductor layer 39A includes a coupling portion V3 having a first surface at the level lower than the second surface of the extension of the conductor layer 39A, and a second surface in contact with the conductor layer 132.

According to such a configuration, the coupling portion V1 has a shape in which, for example, a space present on the other side from the first surface of the insulator layer 44 (the second surface of the aforementioned extension) is not fully occluded but is partially filled. Also, the coupling portion V3 has a shape in which, for example, a space present on the other side from the first surface of the insulator layer 44 (the second surface of the aforementioned extension) is not fully occluded but is partially filled. Due to the above configuration, the conductor layer 39A includes a profile that shows level differences in the coupling portions V1 and V3.

Note that, while FIG. 44 shows only one coupling portion V1, there may be multiple coupling portions V1.

The fourth modification of the second embodiment also produces effects equivalent to those of the second embodiment.

### 4.5 Fifth Modification of Second Embodiment

The second embodiment, the first modification of the second embodiment, the second modification of the second embodiment, the third modification of the second embodiment, and the fourth modification of the second embodiment have assumed a configuration in which the interconnect provided on the first surface of the insulator layer 45 in the region R2 or R3 is constituted by multiple conductor layers, but this is not a limitation. This interconnect may be formed of a single conductor layer. The description will basically concentrate on the particulars of a configuration and a manufacturing method of a semiconductor memory device 1 according to a fifth modification of the second embodiment, which constitute differences from the configuration and the manufacturing method of the semiconductor memory device 1 according to the second embodiment.

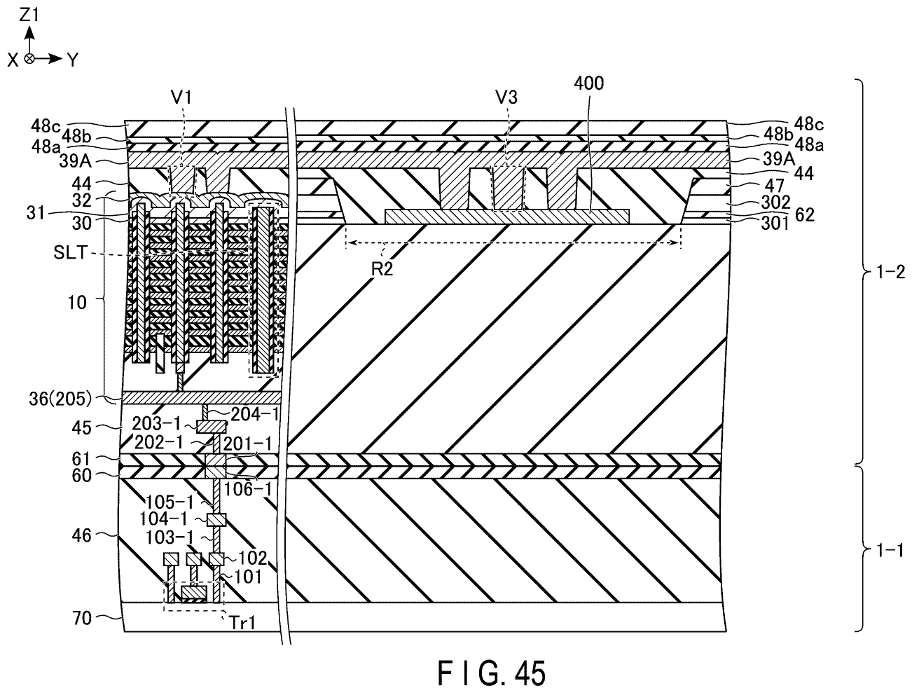

A configuration of the semiconductor memory device 1 according to the fifth modification of the second embodiment will be described with reference to FIG. 45. FIG. 45 is a sectional view showing an exemplary sectional structure of a circuit region CR in the semiconductor memory device 1 according to the fifth modification of the second embodiment.

The semiconductor memory device 1 according to the fifth modification of the second embodiment includes a conductor layer 400. The conductor layer 400 is provided on a portion of the first surface of the insulator layer 45 in the region R2. The conductor layer 400 has a first surface in contact with one or more coupling portions V3 of the conductor layer 39A. The conductor layer 400 is made of a conductive material. In one example, this conductive material contains tungsten, aluminum, titanium, and/or titanium nitride.

Note that, in one example of the fifth modification of the second embodiment, the conductor layers 31A and 32A are not provided on the two wall surfaces sandwiching the region R2 in the Y direction and constituted by the semiconductor layers 301 and 302 and the insulator layers 47 and 62.

A method for manufacturing the semiconductor memory device 1 according to the fifth modification of the second embodiment will be described.

For the fifth modification of the second embodiment, the process discussed with reference to FIG. 30 for the second embodiment is conducted, for example, in such a manner that while the insulator layer 47 and the semiconductor layer 302 in the location corresponding to the memory cell array 10 are removed, removal of these layers in the location corresponding to the region R2 does not take place. That is, the state where the insulator layer 47 and the semiconductor layer 302 in the location corresponding to the region R2 are included is maintained.

Subsequently, for example, the semiconductor layers 301 and 302 and the insulator layers 47 and 62 in the location corresponding to the region R2 are removed. With this removal, the entire first surface of the insulator layer 45 in the location corresponding to the region R2 is exposed at the surface in the part corresponding to FIG. 45.

Then, as one example, the conductor layer 400 is formed on a portion of the exposed first surface of the insulator layer 45 in the location corresponding to the region R2.

The fifth modification of the second embodiment also produces effects equivalent to those of the second embodiment.

### 4.6 Sixth Modification of Second Embodiment

The second embodiment has assumed a configuration in which the conductor layer having an electrode pad is directly coupled to the multiple contacts, but this is not a limitation. As in the first embodiment, the conductor layer having an electrode pad may be coupled to the multiple contacts via a plate-shaped conductor layer. The description will basically concentrate on the particulars of a configuration and a manufacturing method of a semiconductor memory device 1 according to a sixth modification of the second embodiment, which constitute differences from the configuration and the manufacturing method of the semiconductor memory device 1 according to the second embodiment.

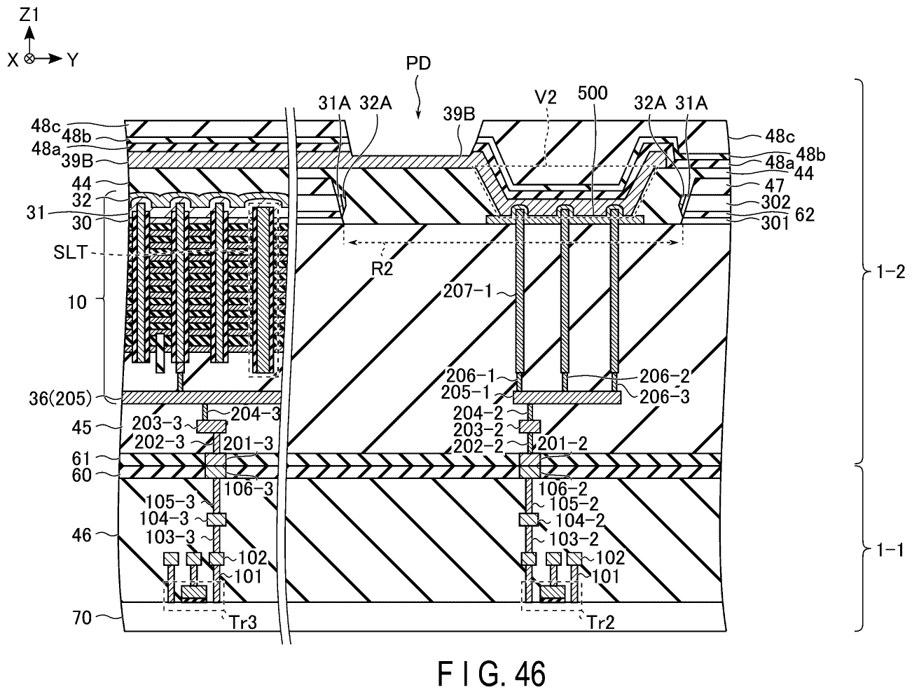

A configuration of the semiconductor memory device 1 according to the sixth modification of the second embodiment will be described with reference to FIG. 46. FIG. 46 is a sectional view showing an exemplary sectional structure of a circuit region CR in the semiconductor memory device 1 according to the sixth modification of the second embodiment. The sectional structure shown in FIG. 46 corresponds to the sectional structure according to the second embodiment shown in FIG. 29. A description will be given of the particulars of the sectional structure shown in FIG. 46, which constitute differences from the sectional structure shown in FIG. 29.

In the sixth modification of the second embodiment, a conductor layer 500 is provided on the one-side portions of the multiple conductor layers 207 and the portions of the first surface of the insulator layer 45 that surround the multiple conductor layers 207. The conductor layer 500 is formed so as to cover the one-side portions of the multiple conductor layers 207. In one example, the conductor layer 500 is formed to have a pattern which extends over the X-Y plane in a plate shape. In one example, the first surface of the conductor layer 500 has a dent and rise profile corresponding to the multiple conductor layers 207. That is, the conductor layer 500 may have a non-flat first surface. However, the first surface of the conductor layer 500 is not limited to this and may instead be flat.

Note that, in the sixth modification of the second embodiment, the first surface of the insulator layer 45 in the region R2 has a uniform height and is at the same level as the second surface of the conductor layer 30 in the memory cell array 10.

The conductor layer 39B is provided so as to be in contact with the first surface of the conductor layer 500, instead of being in direct contact with the multiple conductor layers 207 as in the second embodiment.

In the method for manufacturing the semiconductor memory device 1 according to the sixth modification of the second embodiment, for example, the conductor layer 500 is formed to be in contact with the multiple conductor layers 207 after the step corresponding to FIG. 35 in the second embodiment. Also, the conductor layer 500 may be formed in the same step as the step for forming the conductor layer 32, as in the case of the conductor layer 32B in the first embodiment.

The sixth modification of the second embodiment also produces effects equivalent to those of the second embodiment.

### 5 Others

While certain embodiments have been described, these embodiments have been presented by way of example only, and are not intended to limit the scope of the inventions. Indeed, the novel embodiments described herein may be embodied in a variety of other forms. Furthermore, various omissions, substitutions, and changes in the form of the embodiments may be made without departing from the spirit of the inventions. The accompanying claims and their equivalents are intended to cover such forms or modifications as would fall within the scope and spirit of the inventions.

What is claimed is:

1. A semiconductor memory device comprising:
a first chip comprising a substrate defining a first region and a second region; and
a second chip contacting the first chip in a first direction crossing a surface of the substrate, the second chip being electrically connected to the first chip via a plurality of connection pads at a boundary region between the first chip and the second chip,
the second chip comprising
a memory cell array in the first region, the memory cell array comprising a source line, a plurality of word lines mutually separated in the first direction below the source line, and a memory pillar extending in the first direction, crossing the word lines, and comprising an upper end coupled to the source line,
a plurality of contacts in the second region, the contacts extending in the first direction and each electrically connected to one of the connection pads,
a conductor pattern contacting upper ends of the contacts, and
a first interconnect extending above the conductor pattern and electrically connected to the conductor pattern.

2. The semiconductor memory device according to claim 1, wherein the second chip further comprises a first coupling portion between the conductor pattern and the first interconnect in the first direction, the first coupling portion contacting the conductor pattern and the first interconnect.

3. The semiconductor memory device according to claim 1, wherein the first interconnect comprises
a first extension extending in a second direction crossing the first direction, the first extension being above an upper surface of the source line in the first direction, and
a first coupling portion between the first extension and the conductor pattern in the first direction, the first coupling portion contacting the first extension and the conductor pattern.

4. The semiconductor memory device according to claim 1, wherein the first interconnect comprises a region exposed at an upper surface of the device and constituting an electrode pad.

5. The semiconductor memory device according to claim 4, wherein the electrode pad overlaps the conductor pattern in top view.

6. The semiconductor memory device according to claim 4, wherein the second chip further comprises
a pattern portion in the second region, the pattern portion being included in a same layer level as the source line, a part of the pattern portion that overlaps the contacts in top view having been removed, and
a first insulator portion in the second region, the first insulator portion and the pattern portion being arranged in a second direction crossing the first direction,
the conductor pattern and the electrode pad overlap the first insulator portion in top view, and
the electrode pad is at a position differing from a position of the conductor pattern in top view.

7. The semiconductor memory device according to claim 3, wherein the first interconnect comprises
a lower sub-layer comprising the first coupling portion and a part of the first extension that contacts the first coupling portion, and
an upper sub-layer comprising a remainder of the first extension.

8. The semiconductor memory device according to claim 4, wherein the conductor pattern is smaller than the electrode pad in top view.

9. The semiconductor memory device according to claim 1, wherein the conductor pattern is included in a same layer level as the source line.

10. The semiconductor memory device according to claim 1, wherein the second chip further comprises a second interconnect in the first region, the second interconnect comprising a second coupling portion contacting an upper surface of the source line and a second extension electrically connected to the source line via the second coupling portion and extending above the source line.

11. A semiconductor memory device comprising:
a first chip comprising a substrate defining a first region and a second region; and
a second chip contacting the first chip in a first direction crossing a surface of the substrate, the second chip being electrically connected to the first chip via a plurality of connection pads at a boundary region between the first chip and the second chip,
the second chip comprising
a memory cell array in the first region, the memory cell array comprising a source line, a plurality of word lines mutually separated in the first direction below the source line, and a memory pillar extending in the first direction, crossing the word lines, and comprising an upper end coupled to the source line,
a contact in the second region, the contact extending in the first direction and electrically connected to one of the connection pads,
a first conductor layer in the second region, the first conductor layer being included in a same layer level as the source line and arranged at a position not overlapping the contact in top view and separated from the source line,
a first interconnect layer above the first conductor layer, the first interconnect layer comprising a portion electrically connected to the first conductor layer and a portion electrically connected to the contact, and
a pattern portion in the second region, the pattern portion being included in the same layer level as the source line, a part of the pattern portion that overlaps the contact and the first conductor layer in top view having been removed.

12. The semiconductor memory device according to claim 11, wherein
the second chip further comprises a second conductor layer in the second region, the second conductor layer being below the first conductor layer and included in the same layer level as the source line, and
the source line comprises a third conductor layer and a fourth conductor layer above the third conductor layer,
the first conductor layer and the fourth conductor layer comprising a first conductive material,
the second conductor layer and the third conductor layer comprising a second conductive material.

13. The semiconductor memory device according to claim 11, wherein the portion of the first interconnect layer that is electrically connected to the first conductor layer is electrically connected to the source line in the first region.

14. The semiconductor memory device according to claim 11, wherein
the portion of the first interconnect layer that is electrically connected to the first conductor layer comprises a first sub-interconnect portion and a second sub-interconnect portion which are included in a same layer level as each other and are separate from each other, and
the first sub-interconnect portion and the second sub-interconnect portion extend in parallel to the substrate.

15. The semiconductor memory device according to claim 11, wherein
the first conductor layer comprises a first portion and a second portion separate from each other and facing each other in a direction parallel to the substrate, the first portion and the second portion each having a comb pattern in top view, and
the portion of the first interconnect layer that is electrically connected to the first conductor layer comprises a third sub-interconnect portion and a fourth sub-interconnect portion which are included in a same layer level as each other and are electrically connected to the first portion and the second portion of the first conductor layer, respectively.

16. The semiconductor memory device according to claim 11, wherein
the first interconnect layer comprises a fifth sub-interconnect portion separate from the portion of the first interconnect layer that is electrically connected to the first conductor layer,
the first conductor layer comprises a plate pattern extending over a plane parallel to the substrate,
the portion of the first interconnect layer that is electrically connected to the first conductor layer extends above one side portion of the plate pattern, and
the fifth sub-interconnect portion of the first interconnect layer has a plate shape extending over the plane parallel to the substrate and overlaps the plate pattern at a position differing from the one side portion of the plate pattern in top view.

17. The semiconductor memory device according to claim 11, wherein the first interconnect layer comprises a coupling portion contacting an upper surface of the first conductor layer, and an extension continuously extending in a second direction crossing the first direction from an upper end of the coupling portion and above an upper surface of the source line in the first direction,
the coupling portion having a shape in which a trench above the first conductor layer in the first direction is filled up to a level of a lower surface of the extension in the first direction.

18. The semiconductor memory device according to claim 11, wherein the first interconnect layer comprises a coupling portion contacting an upper surface of the first conductor layer, and an extension continuously extending in a second direction crossing the first direction from an upper end of the coupling portion and above an upper surface of the source line in the first direction,
the coupling portion having a shape in which a trench above the first conductor layer in the first direction is partially filled.

19. The semiconductor memory device according to claim 11, wherein the portion of the first interconnect layer that is electrically connected to the first conductor layer comprises a region exposed at an upper surface of the device and constituting an electrode pad.

20. The semiconductor memory device according to claim 11, wherein
the second chip further comprises a conductor pattern in the second region, the conductor pattern being separate from each of the source line and the first conductor layer and contacting an upper end of the contact,
the portion of the first interconnect layer that is electrically connected to the contact is provided on the conductor pattern, and
the pattern portion has a structure in which, as well as the part that overlaps the contact and the first conductor layer in top view, a part that overlaps the conductor pattern in top view has been removed.
